(19) United States
(12) Patent Application Publication
(10) Pub. No.: US 2024/0407241 A1
(43) Pub. Date: Dec. 5, 2024

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Youngyik KO, Beijing (CN); Chi YU, Beijing (CN); Benlian WANG, Beijing (CN); Gukhwan SONG, Beijing (CN); Ge WANG, Beijing (CN); Zhiliang JIANG, Beijing (CN); Ming HU, Beijing (CN)

(21) Appl. No.: 18/699,600

(22) PCT Filed: Aug. 15, 2023
(86) PCT No.: PCT/CN2023/113072

§ 371 Date: Apr. 9, 2024

(30) Foreign Application Priority Data
Sep. 22, 2022 (CN) 202211160598.1

(51) Int. Cl. H10K 59/80; H10K 59/12; H10K 59/121; H10K 59/131; H10K 59/65

(52) U.S. Cl. CPC H10K 59/8792; H10K 59/1201; H10K 59/1213; H10K 59/1216; H10K 59/131; H10K 59/65

(57) ABSTRACT

A display substrate, comprising: a base, a circuit structure layer, a light-transmitting structure layer, and a light-emitting structure layer. The circuit structure layer is located in a second region and comprises a plurality of first pixel circuits. The light-transmitting structure layer is located in a first region and comprises a shielding layer and at least one connecting layer. Orthographic projections of the shielding layer and of at least one connecting layer at least partially overlap on the base. The at least one connecting layer comprises a plurality of first connecting lines, at least one first connecting line extending from the first region to the second region. The light-emitting structure layer comprises a plurality of first light-emitting elements located in the first region. At least one first light-emitting element is electrically connected to at least one first pixel circuit by means of at least one first connecting line.

### CROSS-REFERENCE TO RELATED APPLICATION

The present application is a U.S. National Phase Entry of International Application No. PCT/CN2023/113072 having an international filing date of Aug. 15, 2023, which claims priority to Chinese Patent Application No. 202211160598.1 filed to the CNIPA on Sep. 22, 2022 and entitled “Display Substrate and Preparation Method Therefor, and Display Apparatus”. The above-identified applications are incorporated into the present application by reference in their entireties.

### TECHNICAL FIELD

The present disclosure relates to, but is not limited to, the field of display technologies, and particularly to a display substrate and a preparation method therefor, and a display apparatus.

### BACKGROUND

An Organic Light Emitting Diode (OLED) and a Quantum dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc. An under screen camera technology is a brand-new technology proposed for increasing a screen-to-body ratio of a display apparatus.

### SUMMARY

The following is a summary of subject matters described herein in detail. The summary is not intended to limit the scope of protection of the claims.

Embodiments of the present disclosure provide a display substrate, a method for manufacturing the display substrate, and a display apparatus.

In one aspect, an embodiment of the present disclosure provides a display substrate including a base substrate, a circuit structure layer, a light transmitting structure layer, and a light emitting structure layer. The base substrate includes a first region and a second region located on at least one side of the first region. The circuit structure layer is located in the second region and at least includes a plurality of first pixel circuits. The light transmitting structure layer is located in the first region and includes a shielding layer and at least one connection layer. An orthographic projection of the shielding layer on the base substrate is at least partially overlapped with an orthographic projection of the at least one connection layer on the base substrate. The at least one connection layer includes a plurality of first connection lines, and at least one of the plurality of first connection lines extends from the first region to the second region. The light emitting structure layer is located at a side of the circuit structure layer and the light transmitting structure layer away from the base substrate, and at least includes a plurality of first light emitting elements located in the first region. At least one of the plurality of first light emitting elements in the first region is electrically connected to at least one of the plurality of first pixel circuits in the second region through at least one first connection line. The light emitting structure layer includes a patterned cathode located in the first region. The shielding layer is configured as a shielding structure in a cathode patterning process such that an orthographic projection of the patterned cathode on the base substrate is at least partially overlapped with an orthographic projection of the shielding layer on the base substrate.

In some exemplary embodiments, the shielding layer is located at a side of the at least one connection layer close to the base substrate.

In some exemplary embodiments, a material of the at least one connection layer is a metallic material or an oxide material.

In some exemplary embodiments, the shielding layer includes a shielding strip extending along a first direction, and a plurality of shielding blocks connected to the shielding strip. In the first region, an orthographic projection of an extended part of at least one first connection line of the at least one connection layer along the first direction on the base substrate is within a range of an orthographic projection of the shielding strip on the base substrate.

In some exemplary embodiments, the first region includes a first sub-region and a second sub-region, the second sub-region is located on at least one side of the first sub-region. The shielding layer of the second sub-region includes a shielding strip extending along the first direction and a plurality of shielding blocks connected with the shielding strip. The shielding layer of the first sub-region includes a plurality of shielding blocks independently arranged.

In some exemplary embodiments, a material of the first connection line electrically connected to at least one first light emitting element in the second sub-region is different from a material of a first connection line electrically connected to at least one first light emitting element in the first sub-region.

In some exemplary embodiments, the shielding strip and a plurality of shielding blocks connected to the shielding strip are of an integral structure.

In some exemplary embodiments, the light emitting structure layer further includes a patterned anode located in the first region, an orthographic projection of the anode in the first region on the base substrate is within a range of an orthographic projection of the shielding layer on the base substrate.

In some exemplary embodiments, the circuit structure layer includes a first conductive layer, a semiconductor layer, a second conductive layer, a third conductive layer, a fourth conductive layer, and a fifth conductive layer disposed on the base substrate. The shielding layer is disposed in the same layer as one of the first conductive layer, the second conductive layer, the third conductive layer, the fourth conductive layer and the fifth conductive layer, and the at least one connection layer and the shielding layer are located in different film layers.

In some exemplary embodiments, the circuit structure layer further includes a first transparent conductive layer, a second transparent conductive layer, and a third transparent conductive layer located at a side of the fourth conductive layer away from the base substrate. The at least one connection layer is disposed in the same layer as at least one of the first transparent conductive layer, the second transparent conductive layer and the third transparent conductive layer.

In some exemplary embodiments, the plurality of first light emitting elements of the first region include a first light emitting element that emits light of a first color, a first light emitting element that emits light of a second color, a first light emitting element that emits light of a third color, and a first light emitting element that emits a fourth color light. The shielding layer at least includes a first shielding block, a second shielding block, a third shielding block and a fourth shielding block. The first shielding block, the second shielding block, the third shielding block and the fourth shielding block are disposed along the first direction. An orthographic projection of an anode of the first light emitting element emitting light of the first color on the base substrate is within a range of an orthographic projection of the first shielding block on the base substrate, an orthographic projection of an anode of the first light emitting element emitting light of the second color on the base substrate is within a range of an orthographic projection of the second shielding block on the base substrate, an orthographic projection of an anode of the first light emitting element emitting light of the third color on the base substrate is within a range of an orthographic projection of the third shielding block on the base substrate, an orthographic projection of an anode of the first light emitting element emitting the fourth color light on the base substrate is within a range of an orthographic projection of the fourth shielding block on the base substrate.

In some exemplary embodiments, the shielding layer further includes a shielding strip connecting the first shielding block, the second shielding block, the third shielding block, and the fourth shielding block. The first shielding block, the second shielding block and the third shielding block are located at a side of the shielding strip in a second direction, and the fourth shielding block is located at another side of the shielding strip in the second direction. The second direction intersects with the first direction.

In some exemplary embodiments, the shielding layer further includes a shielding strip connecting the first shielding block, the second shielding block, the third shielding block, and the fourth shielding block. The first shielding block and the third shielding block are located at a side of the shielding strip in the second direction, and the second shielding block and the fourth shielding block are located at another side of the shielding strip in the second direction. The second direction intersects with the first direction.

In some exemplary embodiments, the shielding layer is located at a side of the at least one connection layer away from the base substrate; the shielding layer includes a hollow part, the at least one first connection line is electrically connected with an anode of the first light emitting element through an anode connection via, and an orthographic projection of the anode connection via on the base substrate is within a range of an orthographic projection of the hollow part on the base substrate.

In another aspect, an embodiment of the present disclosure provides a display apparatus, which includes the aforementioned display substrate and a sensor located at a non-display side of the display substrate, and an orthographic projection of the sensor on the display substrate is overlapped with the first region of the display substrate.

In another aspect, an embodiment of the present disclosure provides a preparation method for a display substrate, and the display substrate includes a first region and a second region located on at least one side of the first region. The preparation method includes the following acts: forming a light transmitting structure layer on the base substrate of the first region and forming a circuit structure layer on the base substrate of the second region; forming a light emitting structure layer at a side of the circuit structure layer and the light transmitting structure layer away from the base substrate, wherein the light emitting structure layer at least includes a plurality of first light emitting elements located in the first region; and forming a patterned cathode of the light emitting structure layer in the first region. The circuit structure layer at least includes a plurality of first pixel circuits. The light transmitting structure layer includes a shielding layer and at least one connection layer, wherein the at least one connection layer includes a plurality of first connection lines, and at least one first connection line of the plurality of first connection lines extends from the first region to the second region. An orthographic projection of the shielding layer on the base substrate is at least partially overlapped with an orthographic projection of the at least one connection layer on the base substrate. At least one of the plurality of first light emitting elements in the first region is electrically connected to at least one of the plurality of first pixel circuits in the second region through at least one first connection line. The shielding layer is configured as a shielding structure in a cathode patterning process such that an orthographic projection of the patterned cathode on the base substrate is at least partially overlapped with an orthographic projection of the shielding layer on the base substrate.

In some exemplary embodiments, forming the light transmitting structure layer on the base substrate of the first region and forming the circuit structure layer on the base substrate of the second region includes: forming a semiconductor layer on the base substrate of the second region, wherein the semiconductor layer at least includes an active layer of a transistor of a first pixel circuit; forming a shielding layer in the first region and forming a second conductive layer in the second region synchronously, wherein the second conductive layer includes a gate electrode of a transistor and a first plate of a storage capacitor of the first pixel circuit; forming a connection layer in the first region and forming a third conductive layer in the second region synchronously, wherein the third conductive layer includes a second plate of the storage capacitor of the first pixel circuit; and forming a fourth conductive layer in the second region, wherein the fourth conductive layer includes a first electrode and a second electrode of the transistor of the first pixel circuit.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a part of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, but are only intended to schematically describe contents of the present disclosure.

FIG. 1 is a schematic diagram of a display substrate according to at least one embodiment of the present disclosure.

FIG. 2 is an equivalent circuit diagram of a pixel circuit according to at least one embodiment of the present disclosure.

FIG. 3 is a partial schematic view of a display substrate according to at least one embodiment of the present disclosure;

FIG. 4 is a schematic partial sectional view of a display substrate according to at least one embodiment of the present disclosure.

FIG. 5A and FIG. 5B are schematic plane views of a shielding layer of a first display region of a display substrate according to at least one embodiment of the present disclosure.

FIG. 6 is a schematic partial plane view of a shielding layer according to at least one embodiment of the present disclosure.

FIG. 7 is a schematic partial plane view of a part of a first display region after forming a connection layer according to at least one embodiment of the present disclosure.

FIG. 8 is a schematic partial plane view of a first display region after forming an anode layer according to at least one embodiment of the present disclosure.

FIG. 9 is a schematic partial plane view of a first display region after forming a pixel define layer according to at least one embodiment of the present disclosure.

FIG. 10 is another partial sectional schematic diagram of a display substrate according to at least one embodiment of the present disclosure.

FIG. 11 is another partial sectional schematic diagram of a display substrate according to at least one embodiment of the present disclosure.

FIG. 12 is another partial sectional schematic diagram of a display substrate according to at least one embodiment of the present disclosure.

FIG. 13 is another partial sectional schematic diagram of a display substrate according to at least one embodiment of the present disclosure.

FIG. 14 is another schematic partial plane view of a first display region after forming an anode layer according to at least one embodiment of the present disclosure.

FIG. 15A and FIG. 15B are other schematic plane views of a shielding layer of a first display region of a display substrate according to at least one embodiment of the present disclosure.

FIG. 16 is another schematic partial plane view of a shielding layer according to at least one embodiment of the present disclosure.

FIG. 17 is another schematic partial plane view of a shielding layer according to at least one embodiment of the present disclosure.

FIG. 18A to FIG. 18D are schematic partial diagrams of a first display region according to at least one embodiment of the present disclosure.

FIG. 19 is a schematic diagram of a display apparatus according to at least one embodiment of the present disclosure.

### DETAILED DESCRIPTION

The embodiments of the present disclosure will be described below with reference to the drawings in detail. Implementation modes may be implemented in multiple different forms. Those of ordinary skills in the art may easily understand such a fact that modes and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one mode of the present disclosure is not necessarily limited to the size, and a shape and a size of one or more components in the drawings do not reflect an actual scale. In addition, the accompanying drawings schematically illustrate ideal examples, and a mode of the present disclosure is not limited to shapes, numerical values, or the like shown in the drawings.

Ordinal numerals “first”, “second”, “third”, etc., in the specification are set not to form limits on numbers but only to avoid confusion between composition elements. In the present disclosure, “a plurality of” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or internal communication inside two elements. Those of ordinary skills in the art may understand meanings of the aforementioned terms in the present disclosure according to situations.

In the specification, “electrical connection” includes connection of composition elements through an element with having some electrical function. The “element having some electrical function” is not particularly limited as long as electrical signals between the connected constituent elements may be transmitted. Examples of the “element having some electrical function” not only include an electrode and a wiring, but also include a switching element such as a transistor, a resistor, an inductor, a capacitor, another element with multiple functions, etc.

In the specification, a transistor refers to an element which at least includes three terminals, i.e., a gate, a drain, and a source. The transistor has a channel region between the drain (drain electrode terminal, drain region, or drain electrode) and the source (source electrode terminal, source region, or source electrode), and a current can flow through the drain, the channel region, and the source. In the specification, the channel region refers to a region through which a current mainly flows.

In the specification, to distinguish two electrodes of a transistor except a gate electrode, one of the electrodes is referred to as a first electrode and the other electrode is referred to as a second electrode. The first electrode may be a source electrode or a drain electrode, and the second electrode may be a drain electrode or a source electrode. In addition, the gate electrode of the transistor is referred to as a control electrode. In a case that transistors with opposite polarities are used, or in a case that a direction of a current is changed during operation of a circuit, or the like, functions of the “source” and the “drain” are sometimes interchangeable. Therefore, the “source” and the “drain” are interchangeable in the specification.

In the specification, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95° . . .

A triangle, rectangle, trapezoid, pentagon, or hexagon, etc. in the specification is not strictly defined, and it may be an approximate triangle, rectangle, trapezoid, pentagon, or hexagon, etc. There may be some small deformations caused by tolerance, and there may be a chamfer, an arc edge, and deformation, etc.

A “light transmittance” in the present disclosure refers to an ability of light to pass through a medium, and is a percentage of luminous flux passing through a transparent or translucent body to its incident luminous flux.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. In following description, “A extends in B direction” means “a main body portion of A extends in B direction”.

For products such as smart terminals, it is usually necessary to set up hardware such as front camera, fingerprint sensor or light sensor. In order to increase the screen-to-body ratio, products such as full screen or narrow bezel usually adopt under-screen fingerprint or under-screen camera technology.

An embodiment of the present disclosure provides a display substrate, which includes a base substrate, a circuit structure layer, a light transmitting structure layer and a light emitting structure layer. The base substrate includes a first region and a second region located on at least one side of the first region. The circuit structure layer is located in the second region and at least includes a plurality of first pixel circuits. The light transmitting structure layer is located in the first region and includes a shielding layer and at least one connection layer. An orthographic projection of the shielding layer on the base substrate is at least partially overlapped with an orthographic projection of at least one connection layer on the base substrate. At least one connection layer includes a plurality of first connection lines, and at least one of the plurality of first connection lines extends from the first region to the second region. The light emitting structure layer is located at a side of the circuit structure layer and the light transmitting structure layer away from the base substrate, and at least includes a plurality of first light emitting elements located in the first region. At least one of the plurality of first light emitting elements in the first region is electrically connected to at least one of the plurality of first pixel circuits in the second region through at least one first connection line. The light emitting structure layer includes a patterned cathode located in the first region. The shielding layer is configured as a shielding structure in a cathode patterning process such that an orthographic projection of the patterned cathode on the base substrate is at least partially overlapped with an orthographic projection of the shielding layer on the base substrate.

In the display substrate provided by the embodiment, the first light emitting element located in the first region and the first pixel circuit located in the second region are electrically connected by the first connection line provided by at least one connection layer, and an orthographic projection of the shielding layer on the base substrate is at least partially overlapped with an orthographic projection of at least one connection layer on the base substrate, so that the influence of the arrangement of the first connection lines on the light transmittance of the first region can be improved.

In some exemplary embodiments, the material of at least one connection layer may be a metallic material or an oxide material. For example, the oxide material may include indium tin oxide (ITO), indium gallium zinc oxide (IGZO).

In some examples, the display substrate may include one or more connection layers made of a metallic material. The electrical connections between the plurality of first pixel circuits and the plurality of first light emitting elements may all be realized by first connection lines made of a metallic material. In other examples, the display substrate may include a plurality of connection layers made of an oxide material. The electrical connections between the plurality of first pixel circuits and the plurality of first light emitting elements may all be realized by transparent first connection lines made of an oxide material. In other examples, the display substrate may include at least one connection layer made of a metallic material and at least one connection layer made of an oxide material. The electrical connections between a part of the first pixel circuits and a part of the first light emitting elements may be realized by first connection lines made of a metallic material, and the electrical connections between another part of the first pixel circuits and another part of the first light emitting elements may be realized by transparent first connection lines made of an oxide material. This embodiment is not limited thereto.

In some examples, the display substrate includes one or more connection layers made of a metallic material, which can reduce the use of transparent conductive layers, thereby reducing the process preparation process and facilitating increase in productivity. Moreover, by preparing one or more connection layers using a metallic material, it is advantageous to increase the number of connection lines between the first light emitting elements and the first pixel circuits, and to increase the size of the first region.

In some exemplary embodiments, the shielding layer may be located at a side of at least one connection layer close to the base substrate. For example, the circuit structure layer may at least include a first conductive layer, a semiconductor layer, a second conductive layer, a third conductive layer, a fourth conductive layer, and a fifth conductive layer disposed on the base substrate, and the shielding layer may be disposed in the same layer as one of the first conductive layer, the second conductive layer, the third conductive layer, the fourth conductive layer, and the fifth conductive layer and formed simultaneously by the same patterning process. The connection layer may be located at a different film layer from the shielding layer. For example, the shielding layer is disposed in the same layer as the first conductive layer, and the connection layer may be disposed in the same layer as any of the second conductive layer to the fifth conductive layer. As another example, the shielding layer is disposed in the same layer as the second conductive layer, and the connection layer may be disposed in the same layer as any of the third conductive layer to the fifth conductive layer. However, the embodiment is not limited thereto. In other examples, the shielding layer may be located at a side of the connection layer away from the base substrate. For example, the shielding layer may be disposed in the same layer as the fifth conductive layer and formed simultaneously by the same patterning process, and the connection layer may be disposed in the same layer as any of the first conductive layer to the fourth conductive layer and formed simultaneously by the same patterning process.

In some exemplary embodiments, the shielding layer may include a shielding strip extending along a first direction, and a plurality of shielding blocks connected to the shielding strip. In the first region, an orthographic projection of an extended part of at least one first connection line of at least one connection layer along the first direction on the base substrate may be located within a range of an orthographic projection of the shielding strip on the base substrate. In this example, the first connection line of the connection layer is at least partially shielded by the shielding strip of the shielding layer, so that the influence of the connection layer on the light transmittance of the first region can be avoided, and the space can be fully utilized to realize the trace arrangement.

In some exemplary embodiments, the first region may include a first sub-region and a second sub-region, and the second sub-region may be located on at least one side of the first sub-region. The shielding layer of the second sub-region may include a shielding strip extending in a first direction and a plurality of shielding blocks connected with the shielding strip. The shielding layer of the first sub-region may include a plurality of shielding blocks independently arranged. In the present example, removing the shielding strips of the shielding layer in a partial region within the first region can facilitate the improvement for diffraction caused by many shielding strips. In some exemplary embodiments, a material of the first connection line electrically connected to at least one first light emitting element in the second sub-region may be different from a material of a first connection line electrically connected to at least one first light emitting element in the first sub-region. For example, at least one first light emitting element in the second sub-region may be electrically connected to at least one first pixel circuit of the second region through a first connection line made of a metallic material, and at least one first light emitting element in the first sub-region may be electrically connected to at least one first pixel circuit of the second region through a first connection line made of an oxide material. In this way, the light transmittance of the first region can be improved and the diffraction can be improved. However, the embodiment is not limited thereto. In other examples, at least one first light emitting element within the first sub-region may also be electrically connected to at least one first pixel circuit of the second region through the first connection line made of a metallic material.

In some exemplary embodiments, the light emitting structure layer may further include a patterned anode located in the first region, an orthographic projection of the anode in the first region on the base substrate is within a range of an orthographic projection of the shielding layer on the base substrate. In this example, by covering the anode of the first region with the shielding layer, the anode of the first region can be protected and the light transmittance of the first region can be ensured, and the influence of the cathode patterning process on the anode can be avoided.

Solutions of the embodiments will be described below through some examples.

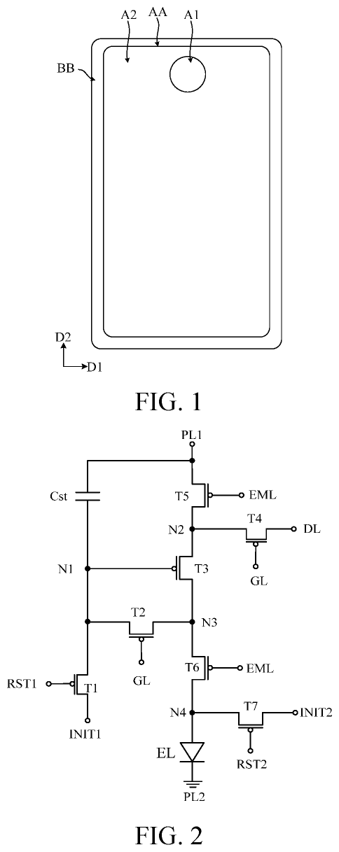

FIG. 1 is a schematic diagram of a display substrate according to at least one embodiment of the present disclosure. In some examples, as shown in FIG. 1, the display substrate may include a display region AA and a peripheral region BB surrounding a periphery of the display region AA. The display region AA of the display substrate may include a first display region A1 and a second display region A2. The second display region A2 may at least partially surround the first display region A1. In the example, the second display region A2 may surround the first display region A1. In this example, the aforementioned first region may be a first display region A1, and the aforementioned second region may be a second display region A2. In other examples, the aforementioned second region may be a peripheral region BB.

In some examples, as shown in FIG. 1, the first display region A1 may be a light transmitting display region, and may also be called an FDC (Full Display With Camera) region configured for image display and light transmission, the second display region A2 may be a normal display region configured to perform image display. For example, an orthographic projection of a photosensitive sensor (such as a camera and other hardware) on the display substrate may be located within the first display region A1 of the display substrate. In some examples, as shown in FIG. 1, the first display region A1 may be circular, and a size of an orthographic projection of the sensor on the display substrate may be less than or equal to a size of the first display region A1. However, the embodiment is not limited thereto. In some other examples, the first display region A1 may be rectangular, and a size of the orthographic projection of the sensor on the display substrate may be less than or equal to a size of an inscribed circle of the first display region A1.

In some examples, as shown in FIG. 1, a ratio of the resolution of the second display region A2 to the resolution of the first display region A1 may be about 0.8 to 1.2. Or, the resolution of the second display region A2 is approximately the same as that of the first display region A1. The resolution of the first display region A1 may be greater than 400, for example.

In some examples, as shown in FIG. 1, the first display region A1 may be located at a middle position of a top of the display region AA. The second display region A2 may surround the first display region A1. However, the embodiment is not limited thereto. For example, the first display region A1 may be located at another position such as an upper left corner or an upper right corner of the display region AA. For example, the second display region A2 may surround at least one side of the first display region A1.

In some examples, as shown in FIG. 1, the display region AA may be in a shape of a rectangle, e.g., a rounded rectangle. The first display region A1 may be circular or elliptical. However, the embodiment is not limited thereto. For example, the first display region A1 may be rectangular, semicircular, pentagonal, or have another shape.

In some examples, the display region AA may be provided with a plurality of sub-pixels. At least one sub-pixel may include a pixel circuit and a light emitting element. The pixel circuit may be configured to drive a connected light emitting element. For example, the pixel circuit is configured to provide a drive current to drive the light emitting element to emit light. The pixel circuit may include a plurality of transistors and at least one capacitor. For example, the pixel circuit may be of a 3TIC, 4TIC, 5TIC, 5T2C, 6TIC, 7TIC, or 8TIC structure. Among them, in the above circuit structure, T refers to a thin film transistor, C refers to a capacitor, a number before T represents a quantity of thin film transistors in the circuit, and a number before C represents a quantity of capacitors in the circuit.

In some examples, the plurality of transistors in the pixel circuit may be P-type transistors or may be N-type transistors. Use of a same type of transistors in the pixel circuit may simplify a process flow, reduce a process difficulty of the display substrate, and improve a yield of products. In other examples, the plurality of transistors in the pixel circuit may include a P-type transistor and an N-type transistor.

In some examples, low temperature poly silicon thin film transistors, or oxide thin film transistors, or a low temperature poly silicon thin film transistor and an oxide thin film transistor may be adopted for the plurality of transistors in the pixel circuit. Low Temperature Poly Silicon (LTPS) is adopted for an active layer of a low temperature poly silicon thin film transistor and an oxide semiconductor (Oxide) is adopted for an active layer of an oxide thin film transistor. The low temperature poly silicon thin film transistor has advantages such as a high migration rate and fast charging, and the oxide thin film transistor has advantages such as a low leakage current. The low temperature poly silicon thin film transistor and the oxide thin film transistor are integrated on one display panel, that is, an LTPS+Oxide (LTPO for short) display panel, advantages of both the low temperature poly silicon thin film transistor and the oxide thin film transistor may be utilized, so that low-frequency drive may be achieved, power consumption may be reduced, and display quality may be improved.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under drive of a pixel circuit corresponding to the light emitting element. A color of light emitted by the light emitting element may be determined as required. In some examples, the light emitting element may include an anode, a cathode, and an organic emitting layer located between the anode and the cathode. The anode of the light emitting element may be electrically connected with a corresponding pixel circuit. However, the embodiment is not limited thereto.

In some examples, one pixel unit of the display region AA may include three sub-pixels, and the three sub-pixels may be a red sub-pixel, a green sub-pixel, and a blue sub-pixel, respectively. However, the embodiment is not limited thereto. In some examples, one pixel unit may include four sub-pixels, wherein the four sub-pixels may be a red sub-pixel, a green sub-pixel, a blue sub-pixel, and a white sub-pixel respectively.

In some examples, a shape of the light emitting element may be a rectangle, a rhombus, a pentagon, or a hexagon. When one pixel unit includes three sub-pixels, light emitting elements of the three sub-pixels may be arranged in a manner to stand side by side horizontally, in a manner to stand side by side vertically, or in a manner like a Chinese character “we”. When one pixel unit includes four sub-pixels, light emitting elements of the four sub-pixels may be arranged in a manner to stand side by side horizontally, in a manner to stand side by side vertically, or in a manner to form a square. However, the embodiment is not limited thereto.

FIG. 2 is an equivalent circuit diagram of a pixel circuit according to at least one embodiment of the present disclosure. The pixel circuit of an exemplary embodiment is described by taking a 7TIC structure as an example. However, the embodiment is not limited thereto.

In some examples, as shown in FIG. 2, the pixel circuit of this example may include six switching transistors (T1, T2, and T4 to T7), one drive transistor T3, and one storage capacitor Cst. The six switching transistors are respectively a data writing transistor T4, a threshold compensation transistor T2, a first light emitting control transistor T5, a second light emitting control transistor T6, a first reset transistor T1, and a second reset transistor T7. The light emitting element EL may include an anode, a cathode and an organic emitting layer arranged between the anode and the cathode.

In some examples, as shown in FIG. 2, a display substrate may include a scan line GL, a data line DL, a first power supply line PL1, a second power supply line PL2, an emitting control line EML, a first initial signal line INIT1, a second initial signal line INIT2, a first reset control line RST1, and a second reset control line RST2. In some examples, the first power supply line PL1 may be configured to provide a constant first voltage signal VDD to a pixel circuit, the second power supply line PL2 may be configured to provide a constant second voltage signal VSS to a pixel circuit, and the first voltage signal VDD is greater than the second voltage signal VSS. The scan line GL may be configured to provide a scan signal SCAN to the pixel circuit, the data line DL may be configured to provide a data signal DATA to the pixel circuit, the light emitting control line EML may be configured to provide a light emitting control signal EM to the pixel circuit, the first reset control line RST1 may be configured to provide a first reset control signal RESET1 to the pixel circuit, and the second reset control line RST2 may be configured to provide a second reset control signal RESET2 to the pixel circuit. In some examples, in pixel circuits of an n-th row, a first reset control line RST1 may be electrically connected with a scan line GL of the pixel circuits of an (n−1)-th row to be inputted with a scan signal SCAN (n−1), that is, a first reset control signal RESET1 (n) is the same as the scan signal SCAN (n−1). A second reset control line RST2 may be electrically connected with a scan line GL of pixel circuits of an n-th row to be inputted with a scan signal SCAN (n), that is, a second reset control signal RESET2 (n) is the same as the scan signal SCAN (n). In some examples, a second reset control line RST2 electrically connected with the n-th row of pixel circuits and a first reset control line RST1 electrically connected with the (n+1)-th row of pixel circuits may be of an integral structure. Herein, n is an integer greater than 0. Thus, signal lines of the display substrate may be reduced, and a narrow bezel design of the display substrate may be achieved. However, the embodiment is not limited thereto.

In some examples, the first initial signal line INIT is configured to provide a first initial signal to the pixel circuit, and the second initial signal line INIT2 is configured to provide a second initial signal to the pixel circuit. For example, the first initial signal may be different from the second initial signal. The first initial signal and the second initial signal may be constant voltage signals, and their magnitudes may be between a first voltage signal VDD and a second voltage signal VSS, but not limited to this. In other examples, the first initial signal and the second initial signal may be the same and only the first initial signal line may be set to provide the first initial signal.

In some examples, as shown in FIG. 2, the drive transistor T3 is electrically connected with the light emitting element EL, and outputs a drive current to drive the light emitting element EL to emit light under control of the scan signal SCAN, the data signal DATA, the first voltage signal VDD, and the second voltage signal VSS, etc. A gate of a data writing transistor T4 is electrically connected with a scan line GL, a first electrode of the data writing transistor T4 is electrically connected with a data line DL, and a second electrode of the data writing transistor T4 is electrically connected with a first electrode of the drive transistor T3. A gate of a threshold compensation transistor T2 is electrically connected with a scan line GL, a first electrode of the threshold compensation transistor T2 is electrically connected with a gate of the drive transistor T3, and a second electrode of the threshold compensation transistor T2 is electrically connected with a second electrode of the drive transistor T3. A gate of a first light emitting control transistor T5 is electrically connected with a light emitting control line EML, a first electrode of the first light emitting control transistor T5 is electrically connected with a first power supply line PL1, and a second electrode of the first light emitting control transistor T5 is electrically connected with the first electrode of the drive transistor T3. A gate of the second light emitting control transistor T6 is electrically connected with the light emitting control line EML, a first electrode of the second light emitting control transistor T6 is electrically connected with the second electrode of the drive transistor T3, and a second electrode of the second light emitting control transistor T6 is electrically connected with an anode of the light emitting element EL. The first reset transistor T1 is electrically connected to the gate of the drive transistor T3 and configured to reset the gate of the drive transistor T3, and the second reset transistor T7 is electrically connected to the anode of the light emitting element EL and configured to reset the anode of the light emitting element EL. A gate of the first reset transistor T1 is electrically connected with the first reset control line RST1, a first electrode of the first reset transistor T1 is electrically connected with a first initial signal line INIT1, and a second electrode of the first reset transistor T1 is electrically connected with the gate of the drive transistor T3. A gate of the second reset transistor T7 is electrically connected with the second reset control line RST2, a first electrode of the second reset transistor T7 is electrically connected with a second initial signal line INIT2, and a second electrode of the second reset transistor T7 is electrically connected with the anode of the light emitting element EL. A first capacitance plate of a storage capacitor Cst is electrically connected with the gate of the driving transistor T3, and a second capacitance plate of the storage capacitor Cst is electrically connected with the first power supply line PL1.

In this example, a first node N1 is a connection point of the storage capacitor Cst, the first reset transistor T1, the drive transistor T3, and the threshold compensation transistor T2, a second node N2 is a connection point of the first light emitting control transistor T5, the data writing transistor T4, and the drive transistor T3, a third node N3 is a connection point of the drive transistor T3, the threshold compensation transistor T2, and the second light emitting control transistor T6, and a fourth node N4 is a connection point of the second light emitting control transistor T6, the second reset transistor T7, and the light emitting element EL. The fourth node N4 is an anode connection node.

An operating process of the pixel drive circuit shown in FIG. 2 will be described below. The description is given by taking a case in which a plurality of transistors included in the pixel circuit shown in FIG. 2 are all P-type transistors as an example.

In some exemplary implementation modes, during one-frame display time period, the working process of the pixel circuit may include a first stage, a second stage, and a third stage.

The first stage is referred to as a reset stage. A first reset control signal RESET1 provided by the first reset control line RST1 is a low-level signal, so that the first reset transistor T1 is turned on, and a first initial signal provided by the first initial signal line INITI is provided to the first node N1 to initialize the first node N1 and clear an original data voltage in the storage capacitor Cst. A scan signal SCAN provided by the scan line GL is a high-level signal, and a light emitting control signal EM provided by the light emitting control line EML is a high-level signal, so that the data writing transistor T4, the threshold compensation transistor T2, the first light emitting control transistor T5, the second light emitting control transistor T6, and the second reset transistor T7 are turned off. In this stage, the light emitting element EL does not emit light.

The second stage is referred to as a data writing stage or a threshold compensation stage. A scan signal SCAN provided by the scan line GL is a low-level signal, a first reset control signal RESET1 provided by the first reset control line RST1 and an emitting control signal EM provided by the emitting control line EML are both high-level signals, and the data line DL outputs a data signal DATA. In this stage, the first capacitance plate of the storage capacitor Cst is at a low level, so that the driving transistor T3 is turned on. The scan signal SCAN is a low-level signal, so that the threshold compensation transistor T2, the data writing transistor T4, and the second reset transistor T7 are turned on. The threshold compensation transistor T2 and the data writing transistor T4 are turned on, so that a data voltage Vdata output by the data line DL is provided to the first node NI through the second node N2, the turned-on driving transistor T3, the third node N3, and the turned-on threshold compensation transistor T2, and the storage capacitor Cst is charged with a difference between the data voltage Vdata output by the data line DL and a threshold voltage of the driving transistor T3. A voltage of a first capacitance plate (that is, the first node N1) of the storage capacitor Cst is Vdata−|Vth|, Vdata is the data voltage output by the data line DL, and Vth is the threshold voltage of the driving transistor T3. The second reset transistor T7 is turned on, so that a second initial signal provided by the second initial signal line INIT2 is provided to the anode of the light emitting element EL to initialize (reset) the anode of the light emitting element EL and clear a pre-stored voltage therein, so as to complete initialization, thereby ensuring that the light emitting element EL does not emit light. The first reset control signal RESET1 provided by the first reset control line RST1 is the high-level signal, so that the first reset transistor T1 is turned off. The light emitting control signal EM provided by the light emitting control signal line EML is a high-level signal, so that the first light emitting control transistor T5 and the second light emitting control transistor T6 are turned off.

The third stage is referred to as a light emitting stage. A light emitting control signal EM provided by the light emitting control signal line EML is a low-level signal, and a scan signal SCAN provided by the scan line GL and a first reset control signal RESET1 provided by the first reset control line RST1 are high-level signals. The light emitting control signal EM provided by the light emitting control signal line EML is a low-level signal, so that the first light emitting control transistor T5 and the second light emitting control transistor T6 are turned on, and a first voltage signal VDD output by the first power supply line PLI provides a drive voltage to an anode of the light emitting element EL through the turned-on first light emitting control transistor T5, the drive transistor T3, and the second light emitting control transistor T6 to drive the light emitting element EL to emit light.

In a drive process of the pixel circuit, a drive current flowing through the drive transistor T3 is determined by a voltage difference between the gate and the first electrode of the drive transistor T3. Because the voltage of the first node NI is Vdata-|Vth|, the drive current of the drive transistor T3 is as follows.

$$I = K \times {( V gs - V th )}^{2} = K \times {[ ( V DD - V data + \vert V th \vert ) - V th ]}^{2} = K \times {[ V DD - V data ]}^{2} .$$

Among them, I is the drive current flowing through the drive transistor T3, that is, the drive current for driving the light emitting element EL; K is a constant; Vgs is the voltage difference between the gate and the first electrode of the drive transistor T3; Vth is the threshold voltage of the drive transistor T3; Vdata is the data voltage output by the data line DL; and VDD is the first voltage signal output by the first power supply line PL1.

It may be seen from the above formula that a current flowing through the light emitting element EL has nothing to do with the threshold voltage of the drive transistor T3. Therefore, the pixel circuit of this embodiment can better compensate the threshold voltage of the drive transistor T3.

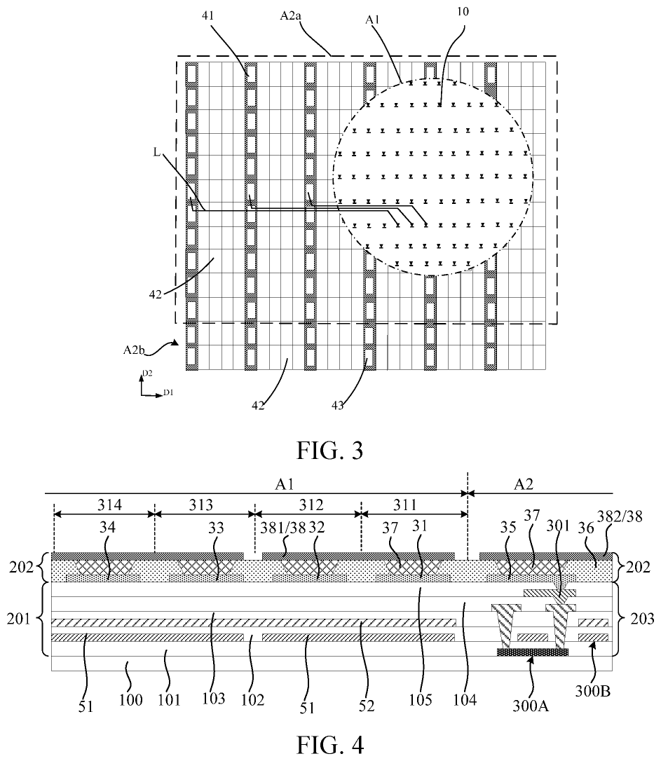

FIG. 3 is a partial schematic view of a display substrate according to at least one embodiment of the present disclosure. In some examples, as shown in FIG. 3, the first display region A2 of the display substrate may include a transition region A2a and a non-transition region A2b. The transition region A2a may be located on at least one side outside the first display region A1 (for example, one side; for another example, left and right sides; for yet another example, all around, i.e., including upper and lower sides and left and right sides).

In some examples, as shown in FIG. 3, the first display region A1 may include a plurality of first light emitting elements 10 arranged in an array. The transition region A2a of the second display region A2 may include a plurality of first pixel circuits 41 and a plurality of second pixel circuits 42 arranged in an array, and may also include a plurality of second light emitting elements (not shown). At least one first pixel circuit 41 in the transition region A2a may be electrically connected to at least one first light emitting element 10 through a connection line L, and is configured to drive the at least one first light emitting element 10 to emit light. For example, one first pixel circuit 41 may be configured to drive two or three or four first light emitting elements 10 emitting the same color light to emit light. An orthographic projection of a first light emitting element 10 on the base substrate may be not overlapped with an orthographic projection of a first pixel circuit 41 electrically connected to the first light emitting element 10 on the base substrate. At least one second pixel circuit 42 in the transition region A2a may be electrically connected to at least one region light emitting element and is configured to drive the at least one second light emitting element to emit light. For example, one second pixel circuit 42 may be configured to drive one second light emitting element to emit light. An orthographic projection of a second pixel circuit 42 may be at least partially overlapped with an orthographic projection of a second light emitting element electrically connected to the second pixel circuit 42 on the base substrate. In the example, by arranging a first pixel circuit 41 for driving the first light emitting elements in the transition region A2a, shielding of light by a pixel circuit may be reduced, thereby increasing a light transmittance of the first display region A1.

In some examples, as shown in FIG. 3, the non-transition region A2b may include a plurality of second pixel circuits 42 and a plurality of invalid pixel circuits 43 arranged in an array, and may further include a plurality of second light emitting elements. The transition region A2a may further include a plurality of invalid pixel circuits 43. It may be beneficial to improving uniformity of components of a plurality of film layers in an etching process by arranging an invalid pixel circuit 43. For example, a structure of a invalid pixel circuit 43 may be substantially the same as structures of a first pixel circuit 41 and a second pixel circuit 42 in a row or column where the invalid pixel circuit is located, except that it is not electrically connected to any light emitting element.

In some examples, since the second display region A2 is not only provided with a second pixel circuit 42 electrically connected with a second light emitting element, but also provided with a first pixel circuit 41 electrically connected with a first light emitting element 10, a quantity of pixel circuits may be greater than a quantity of second light emitting elements in the second display region A2. In some examples, as shown in FIG. 3, a region where newly added pixel circuits (including a first pixel circuit and an invalid pixel circuit) are arranged may be obtained by reducing a size of a second pixel circuit in a first direction D1. For example, a dimension of a pixel circuit in the first direction D1 may be smaller than a dimension of a second light emitting element in the first direction D1. In this example, as shown in FIG. 3, original every a columns of pixel circuits may be compressed along the first direction D1, so that arrangement space of one column of pixel circuits may be added, and space occupied by a columns of pixel circuits before compression and space occupied by a+1 columns of pixel circuits after compression may be the same. Herein, a may be an integer greater than 1. In some examples, a may be equal to 4. However, the embodiment is not limited thereto. For example, a may be equal to 2 or 3.

In other examples, original b rows of pixel circuits may be compressed along a second direction D2, so that arrangement space of one row of pixel circuits is added, and space occupied by b rows of pixel circuits before compression and space occupied by b+1 rows of pixel circuits after compression are the same. Herein, “b” may be an integer greater than 1. Or, a region in which a newly added pixel circuit is disposed may be obtained by reducing dimensions of a second pixel circuit in the first direction D1 and the second direction D2.

In an embodiment of the present disclosure, one row of pixel circuits may include a plurality of pixel circuits arranged in sequence along the first direction D1. A row of pixel circuits may all be adjacent to the same gate line (e.g. scan line). A row of light emitting elements may include a plurality of first light emitting elements and a plurality of second light emitting elements arranged along the first direction D1.

FIG. 4 is a schematic partial sectional view of a display substrate according to at least one embodiment of the present disclosure. The structure of four first light emitting elements in the first display region A1 (for example, a first light emitting element 311 emitting light of a first color, a first light emitting element 312 emitting light of a second color, a first light emitting element 313 emitting light of a third color, and a first light emitting element 314 emitting light of a fourth color) and one sub-pixel in the second display region A2 is illustrated in FIG. 4.

In some examples, in a direction perpendicular to the display substrate, as shown in FIG. 4, the first display region A1 may include: a light transmitting structure layer 201 disposed on the base substrate 100 and a light emitting structure layer 202 located at a side of the light transmitting structure layer 201 away from the base substrate 100. The second display region A2 may include a circuit structure layer 203 disposed on the base substrate 100 and a light emitting structure layer 202 located at a side of the circuit structure layer 203 away from the base substrate 100.

In some examples, as shown in FIG. 4, the light emitting structure layer 202 of the first display region A1 and the second display region A2 may include an anode layer, a pixel define layer 36, an organic light emitting layer 37 and a cathode layer 38. The organic light emitting layer 37 may emit light under the drive of the anode layer and the cathode layer 38. The anode layer of the first display region A1 may include: anodes of first light emitting elements (for example, a first anode 31 of a first light emitting element 311 emitting light of a first color, a second anode 32 of a first light emitting element 312 emitting light of a second color, a third anode 33 of a first light emitting element 313 emitting light of a third color, and a fourth anode 34 of a first light emitting element 314 emitting light of a fourth color). The anode layer of the second display region A2 may include an anode of a second light emitting element (e.g. a fifth anode 35 of a second light emitting element of one sub-pixel). The cathode layer 38 of the first display region A1 may include a patterned first cathode layer 381. The cathode layer 38 of the second display region A2 may include a second cathode layer 382 which may have a full-face structure.

In some examples, as shown in FIG. 4, the circuit structure layer 203 of the second display region A2 may include a plurality of transistors and a storage capacitor constituting a pixel circuit. In FIG. 4, only one transistor and one storage capacitor of one pixel circuit are taken as examples. The circuit structure layer 203 of the second display region A2 may include a semiconductor layer, a first insulation layer 101, a second conductive layer (also referred to as a first gate metal layer), a second insulation layer 102, a third conductive layer (also referred to as a second gate metal layer), a third insulation layer 103, a fourth conductive layer (also referred to as a first source-drain metal layer), a fourth insulation layer 104, a fifth conductive layer (also referred to as a second source-drain metal layer), and a fifth insulation layer 105 that are sequentially disposed on the base substrate 100. The semiconductor layer may include the active layer of the transistor of the pixel circuit located in the second display region A2. The second conductive layer may include a gate electrode of the transistor and a first plate of the storage capacitor of the pixel circuit. The third conductive layer may include a second plate of the storage capacitor of the pixel circuit. The fourth conductive layer may include a first electrode and a second electrode of the transistor of the pixel circuit. The fifth conductive layer may include a first anode connection electrode 301 configured to electrically connect an anode of the second light emitting element and the second pixel circuit.

In some examples, as shown in FIG. 4, the light transmitting structure layer 201 of the first display region A1 may include a first insulation layer 101, a shielding layer 51, a second insulation layer 102, a connection layer 52, a third insulation layer 103, a fourth insulation layer 104, and a fifth insulation layer 105 that are sequentially disposed on the base substrate 100. In this example, one connection layer is taken as an example for illustration. The connection layer 52 and the third conductive layer of the circuit structure layer 203 may be disposed in the same layer. The connection layer 52 may include a plurality of first connection lines that may extend from the first display region A1 to the second display region A2 to electrically connect the first light emitting element of the first display region A1 and the first pixel circuit of the second display region A2. The shielding layer 51 may be disposed in the same layer as the second conductive layer of the circuit structure layer 203. The shielding layer 51 may be configured as a mask structure in the subsequent cathode patterning process, such that an orthographic projection of the patterned cathode on the base substrate 100 may be substantially completely overlapped with an orthographic projection of the shielding layer 51 on the base substrate 100. An orthographic projection of the shielding layer 51 on the base substrate 100 may be at least partially overlapped with an orthographic projection of the connection layer 52 on the base substrate 100. For example, within the first display region A1, the orthographic projection of the connection layer 52 on the base substrate 100 may be within a range of the orthographic projection of the shielding layer 51 on the base substrate 100. In other examples, the display substrate may be provided with two or three connection layers. For example, the two connection layers may be disposed in the same layer as the third conductive layer and the fourth conductive layer, respectively, and the three connection layers may be disposed in the same layer as the third conductive layer, the fourth conductive layer and the fifth conductive layer, respectively. In this example, the first connection line for electrically connecting the first light emitting element and the first pixel circuit is provided by using the connection layer, which is beneficial to increase the number of the first connection lines, thereby being beneficial to increase the size of the first display region. Moreover, the connection layer and at least one conductive layer in the circuit structure layer of the second display region are disposed in the same layer, so that the process preparation steps can be reduced and the productivity can be improved.

Exemplary description is made below for a structure and a manufacturing process of a display substrate. A “patterning process” mentioned in the embodiments of the present disclosure includes a treatment such as photoresist coating, mask exposure, development, etching, and photoresist stripping for a metallic material, an inorganic material, or a transparent conductive material, and includes a treatment such as organic material coating, mask exposure, and development for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a material on a base substrate by using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are of a same layer structure” or “A and B are disposed in a same layer” mentioned in the embodiments of the present disclosure means that A and B are formed simultaneously through a same patterning process, or surfaces of A and B close to a base substrate have basically a same distance from the base substrate, or the surfaces of A and B close to the base substrate are in direct contact with a same film layer. A “thickness” of a film layer is a dimension of the film layer in a direction perpendicular to the display substrate. In an exemplary implementation of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A is overlapped with the boundary of the orthographic projection of B.

In some exemplary implementations, a manufacturing process of the display substrate may include following operations.

(1) Providing a base substrate. In some examples, the base substrate 100 may be a flexible base substrate or may be a rigid base substrate. For example, the rigid base substrate may be made of a material such as glass or quartz. The flexible base substrate may be made of Polyimide (PI) or another material, and the flexible base substrate may be of a single-layer structure or a laminated structure composed of an inorganic material layer and a flexible material layer. However, the embodiment is not limited thereto.

(2) Forming a semiconductor layer. In some examples, a semiconductor thin film is deposited on the base substrate 100 in the second display region A2, and the semiconductor thin film is patterned through a patterning process to form a semiconductor layer in the second display region A2. For example, the semiconductor layer of the second display region may include an active layer of the transistor of the pixel circuit.

In some examples, a material of the semiconductor layer, for example, may include poly-silicon. An active layer may include at least one channel region and a first region and a second region located on two ends of the channel region. The channel region may not be doped with an impurity, and has characteristics of a semiconductor. The first region and the second region may be disposed on two sides of the channel region and doped with impurities, and thus are conductive. The impurities may be changed according to a type of a transistor. In some examples, a doped region of the active layer may be interpreted as a source or a drain of a transistor. A part of the active layer between the transistors may be interpreted as a wiring doped with an impurity, and may be used for electrically connecting the transistors.

(3) Forming a second conductive layer and a shielding layer. In some examples, a first insulation thin film and a second conductive thin film are sequentially deposited on the base substrate 100 where the aforementioned structure is formed, and the second conductive thin film is patterned by a patterning process to form a first insulation layer 101 covering a semiconductor layer, a second conductive layer disposed on the first insulation layer 101 of the second display region A2 and a shielding layer 51 disposed on the first insulation layer 101 of the first display region A1, as shown in FIG. 4. For example, the second conductive layer of the second display region A2 may at least include a gate electrode of the transistor and a first plate of the storage capacitor of the pixel circuit located in the second display region.

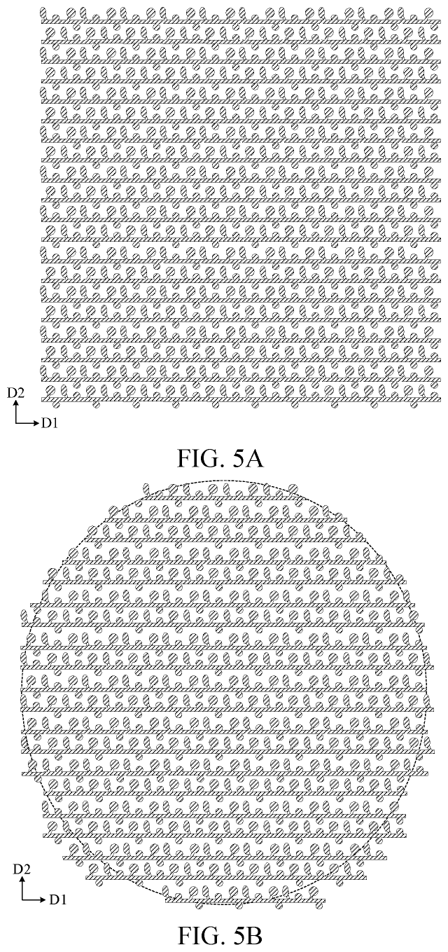

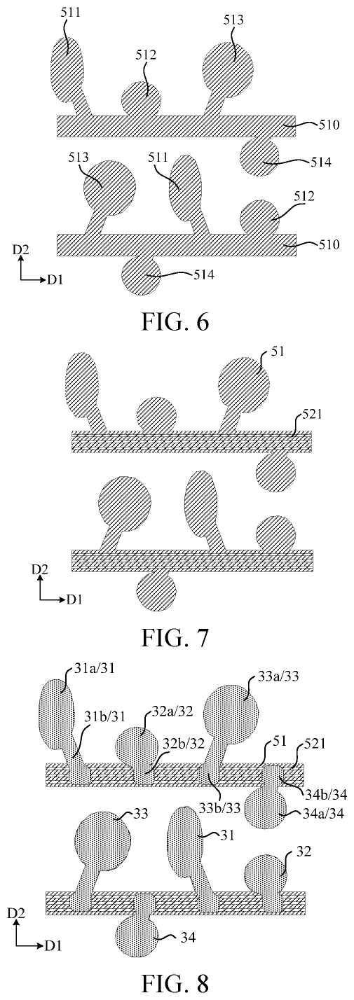

FIG. 5A and FIG. 5B are schematic plane views of a shielding layer of a first display region of a display substrate according to at least one embodiment of the present disclosure. FIG. 6 is a schematic partial plane view of a shielding layer according to at least one embodiment of the present disclosure. As shown in FIG. 5A, the first display region may be rectangular. As shown in FIG. 5B, the first display region may be circular or oval. FIG. 6 illustrates the structure of the shielding layer of two pixel units (including eight first light emitting elements, the first pixel circuits corresponding to the eight first light emitting elements being located in the second display region) in the first display region. The two pixel units corresponding to the shielding layer illustrated in FIG. 6 may be sequentially disposed along the second direction D2, each pixel unit includes four first light emitting elements, and the four first light emitting elements in each pixel unit may be sequentially disposed along the first direction D1. The first direction D1 intersects with the second direction D2. For example, the first direction D1 may be a horizontal direction, and the second direction D2 may be a vertical direction.

In some examples, as shown in FIG. 6, the shielding layer may include a first shielding block 511, a second shielding block 512, a third shielding block 513, a fourth shielding block 514 and a shielding strip 510. The shielding strip 510 may be a strip-shaped structure extending along the first direction D1. The first shielding block 511, the second shielding block 512, the third shielding block 513, and the fourth shielding block 514, which are block-shaped, may be disposed along the first direction D1 and are all connected to the shielding strip 510 to form an integral structure connected to each other. For example, the first shielding blocks 511 and the third shielding block 513 may be connected to the shielding strip 510 through a connection strip, and the second shielding block 512 and the fourth shielding block 514 may be directly connected to the shielding strip 510. The first shielding block 511, the second shielding block 512, and the third shielding block 513 may be located on one side of the connected shielding strip 510 along the second direction D2, and the fourth shielding block 514 may be located on the other side of the connected shielding strip 510 along the second direction D2.

In some examples, as shown in FIG. 6, on a plane parallel to the base substrate, the shape of the first shielding block 511 may be generally elliptical, and the shapes of the second shielding block 512, the third shielding block 513, and the fourth shielding block 514 may be generally circular. However, the embodiment is not limited thereto. For example, the shapes of the first shielding block to the fourth shielding block may include any one or more of the following: rectangle, square, pentagon, and hexagon.

(4) Forming a third conductive layer and a connection layer. In some examples, a second insulation thin film and a third conductive thin film are sequentially deposited on the base substrate 100 where the aforementioned structures are formed, and the third conductive thin film is patterned by a patterning process to form a second insulation layer 102, a third conductive layer disposed on the second insulation layer 102 of the second display region A2 and a connection layer 52 disposed on the second insulation layer 102 of the first display region A1, as shown in FIG. 4. For example, the third conductive layer may include a second plate of the storage capacitor of the pixel circuit. An orthographic projection of the second plate of the storage capacitor on the base substrate 100 may be at least partially overlapped with an orthographic projection of the first plate of the storage capacitor on the base substrate 100.

In some examples, the connection layer 52 may include a plurality of first connection lines. At least one first connection line may extend from the first display region A1 to the second display region A2 so as to electrically connect the anode of the first light emitting element of the first display region A1 and the first pixel circuit of the second display region A2.

FIG. 7 is a schematic partial plane view of a part of a first display region after forming a connection layer according to at least one embodiment of the present disclosure. In some examples, as shown in FIG. 6 and FIG. 7, the first connection line 521 may include an extended part along the first direction D1. In the first display region, an orthographic projection of the extended part of the first connection line 521 along the first direction D1 on the base substrate may be overlapped with an orthographic projection of the shielding strip 510 of the shielding layer 51 on the base substrate. For example, in the first display region, the orthographic projection of one shielding strip 510 on the base substrate may cover the orthographic projections of the extended parts of three first connection lines 521 along the first direction D1 on the base substrate. In other examples, the orthographic projection of one shielding strip in the first display region on the base substrate may cover the orthographic projections of the extended parts of four or more first connection lines 521 along the first direction D1 on the base substrate.

(5) Forming a third insulation layer and a fourth conductive layer. In some examples, a third insulation thin film is deposited on the base substrate 100 where the aforementioned structures are formed, and the third insulation layer 103 is formed by a patterning process. A plurality of active vias are formed on the third insulation layer 103 of the second display region A2, and the plurality of active vias at least include two active vias located in the second display region A2, and the two active vias respectively expose two ends of the active layer of one transistor. Subsequently, a fourth conductive thin film is deposited and patterned by a patterning process to form a fourth conductive layer disposed in the second display region A2, as shown in FIG. 4. For example, the fourth conductive layer may include a first electrode and a second electrode of a transistor of a pixel circuit located in the second display region A2, and the first electrode and the second electrode of the transistor may be connected to two ends of the active layer through the active vias, respectively.

So far, preparation of a pixel circuit of the second display region A2 may be completed. For example, the transistor 300A may include an active layer, a gate electrode, a first electrode and a second electrode. The storage capacitor 300B may include a first plate and a second plate. At this time, the light transmitting structure layer 201 of the first display region A1 may include a first insulation layer 101, a shielding layer 51, a second insulation layer 102, a connection layer 52, and a third insulation layer 103 that are sequentially disposed on the base substrate 100

In some examples, the first insulation layer 101, the second insulation layer 102, and the third insulation layer 103 may be made of any one or more of Silicon Oxide (SiOx), Silicon Nitride (SiNx), and Silicon Oxynitride (SiON), and may be a single layer, a multi-layer, or a composite layer. The first insulation layer 101 and the second insulation layer 102 may be referred to as Gate Insulation (GI) layers, and the third insulation layer 103 may be referred to as an Interlayer Dielectric (ILD) layer. The second conductive layer, the third conductive, the fourth conductive layer, the shielding layer 51 and the connection layer 52 may be made of a metallic material, such as any one or more of Silver (Ag), Copper (Cu), Aluminum (Al), and Molybdenum (Mo), or an alloy material of the aforementioned metals, such as an Aluminum Neodymium alloy (AlNd) or a Molybdenum Niobium alloy (MoNb), and may be of a single-layer structure or a multi-layer composite structure, such as Mo/Cu/Mo, Ti/Al/Ti. The semiconductor layer may be made of various materials, such as amorphous Indium Gallium Zinc Oxide (a-IGZO), Zinc Oxynitride (ZnON), Indium Zinc Tin Oxide (IZTO), amorphous Silicon (a-Si), polycrystalline Silicon (p-Si). That is, the present disclosure is applicable to transistors manufactured based on an oxide technology, a silicon technology, and an organic matter technology.

(6) Forming a fifth conductive layer. In some examples, a fourth insulation thin film is deposited on the base substrate 100 where the aforementioned structures are formed, and the fourth insulation thin film is patterned by a patterning process to form a fourth insulation layer 104. The fourth insulation layer 104 is formed with a plurality of vias in the second display region A2, and the plurality of vias at least include a first connection hole located in the second display region A2. The fourth insulation layer 104 in the first connection hole of each sub-pixel may be removed to expose a first electrode of a transistor of a pixel circuit of the sub-pixel. In some examples, the fourth insulation layer 104 may be made of any one or more of Silicon Oxide (SiOx), Silicon Nitride (SiNx), and Silicon Oxynitride (SiON), and may be a single layer, a multi-layer, or a composite layer. The fourth insulation layer 104 may be referred to as a passivation (PVX) layer.

Subsequently, a fifth conductive thin film is deposited, and the fifth conductive thin film is patterned by a patterning process to form a fifth conductive layer. As shown in FIG. 4, the fifth conductive layer at least includes a first anode connection electrode 301 located in the second display region A2. The first anode connection electrode 301 may be electrically connected to the transistor of the second pixel circuit through the first connection via, and the first anode connection electrode 301 may be configured to be electrically connected to an anode of a second light emitting element that is subsequently formed. In some examples, the fifth conductive layer may further include a second anode connection electrode (not shown) located in the second display region A2, the second anode connection electrode may be electrically connected to the first connection line extending to the second display region A2 through a second connection hole provided in the fourth insulation layer 104, and may also be electrically connected to the first pixel circuit through the first connection hole. The fourth insulation layer 104 and the third insulation layer 103 in the second connection hole may be removed to expose a surface of the first connection line. However, the embodiment is not limited thereto. In other examples, the first electrode of the transistor of the first pixel circuit located in the fourth conductive layer may be electrically connected to the first connection line through a via provided in the third insulation layer so as to be electrically connected to the anode of the first light emitting element through the first connection line.

In some examples, the fifth conductive layer may employ a multilayer composite structure, such as Ti/Al/Ti. However, the embodiment is not limited thereto.

(7) Forming a fifth insulation layer. In some examples, a fifth insulation thin film is coated on the base substrate 100 where the aforementioned structures are formed, and a fifth insulation layer 105 is formed through a patterning process, as show in FIG. 4. The fifth insulation layer 105 may be provided with a plurality of vias, such as a third connection via located in the second display region A2 and a fourth connection via located in the first display region A1. The fifth insulation layer 105 in the third connection via may be removed to expose a surface of the first anode connection electrode 301, and the fifth insulation layer 105, the fourth insulation layer 104 and the third insulation layer 103 in the fourth connection via may be removed to expose a surface of the first connection line. In some examples, the fifth insulation layer 105 may be made of an organic material, such as resin. The fifth insulation layer 105 may also be referred as a planarization layer.

Thus, the preparation of the light transmitting structure layer 201 of the first display region A1 and the circuit structure layer 203 of the second display region A2 is completed. The light transmitting structure layer 201 of the first display region A1 may include a first insulation layer 101, a shielding layer 51, a second insulation layer 102, a connection layer 52, a third insulation layer 103, a fourth insulation layer 104, and a fifth insulation layer 105 that are sequentially disposed on the base substrate 100. The circuit structure layer 203 of the second display region A2 may include a semiconductor layer, a first insulation layer 101, a second conductive layer, a second insulation layer 102, a third conductive layer, a third insulation layer 103, a fourth conductive layer, a fourth insulation layer 104, a fifth conductive layer, and a fifth insulation layer 105 that are sequentially disposed on the base substrate 100.

(8) Forming an anode layer. In some examples, an anode conductive thin film is deposited on the base substrate 100 where the aforementioned structures are formed, and the anode conductive thin film is patterned through a patterning process to form an anode layer. As shown in FIG. 4, the anode layer may include a first anode 31 of a first light emitting element 311 that emits light of a first color, a second anode 32 of a first light emitting element 312 that emits light of a second color, a third anode 33 of a first light emitting element 313 that emits light of a third color, a fourth anode 34 of a first light emitting element 314 that emits light of a fourth color which are located in the second display region A1, and a fifth anode 35 of a second light emitting element that is located in the second display region A2. The fifth Anode 35 may be electrically connected to the first anode connection electrode 301 through a third connection via. In some examples, light of the first color may be red light, light of the second color and the fourth color light may be green light, and light of the third color may be blue light. However, the embodiment is not limited thereto.

FIG. 8 is a schematic partial plane view of a first display region after forming an anode layer according to at least one embodiment of the present disclosure. FIG. 8 illustrates the structure of the anodes of two pixel units (including eight first light emitting elements, the first pixel circuits corresponding to the eight first light emitting elements being located in the second display region) in the first display region. The two pixel units shown in FIG. 8 may be disposed in sequence along the second direction D2, each pixel unit includes four first light emitting elements, and the four first light emitting elements of each pixel unit may be disposed along the first direction D1.

In some examples, as shown in FIG. 8, the first anode 31 may include a first body 31a and a first connection part 31b, the first body 31a may be substantially elliptical, the first connection part 31b is connected to the first body 31a and extends to be electrically connected to a first connection line 521. The second anode 32 may include a second body 32a and a second connection part 32b, the second body 32a may be substantially circular, the second connection part 32b is connected to the second body 32a and extends to be electrically connected to the first connection line 521. The third anode 33 may include a third body 33a and a third extended part 33b, the third body 33a may be substantially circular, the third extended part 33b is connected to the third body 33a and extends to be electrically connected to the first connection line 521. The fourth anode 34 may include a fourth body 34a and a fourth extended part 34b, the fourth body 34a may be substantially circular, the fourth extended part 34b is connected to the fourth body 34a and extends to be electrically connected to the first connection line 521. In other examples, the shapes of the first body 31a, the second body 32a, the third body 33a and the fourth body 34a may be quadrilateral, pentagonal, or hexagonal.

In some examples, as shown in FIG. 6-FIG. 8, within at least one pixel unit, the orthographic projections of the first extended part 31b of the first anode 31, the second extended part 32b of the second anode 32, the third extended part 33b of the third anode 33, and the fourth extended part 34b of the fourth anode 34 on the base substrate may be overlapped with the orthographic projection of the shielding strip 510 of the shielding layer 51 on the base substrate. The orthographic projections of the first anode 31, the second anode 32, the third anode 33, and the fourth anode 34 on the base substrate may be within the range of the orthographic projection of the shielding layer 51 on the base substrate. The position and shape of the first shielding block 511 may be substantially similar to those of the first body 31a of the first anode 31, and an orthographic projection of the first body 31a of the first anode 31 on the base substrate may be positioned within a range of an orthographic projection of the first shielding block 511 of the shielding layer 51 on the base substrate, so that the first shielding block 511 may shield the first anode 31 during subsequent cathode patterning processing to avoid damage to the first anode 31. The position and shape of the second shielding block 512 may be substantially similar to those of the second body 32a of the second anode 32, and an orthographic projection of the second body 32a of the second anode 32 on the base substrate may be within a range of an orthographic projection of the second shielding block 512 on the base substrate, so that the second shielding block 512 may shield the second anode 32 during subsequent cathode patterning processing to avoid damage to the second anode 32. The position and shape of the third shielding block 513 may be substantially similar to those of the third body 33a of the third anode 33, and an orthographic projection of the third body 33a of the third anode 33 on the base substrate may be within a range of an orthographic projection of the third shielding block 513 on the base substrate, so that the third shielding block 513 may shield the third anode 33 during subsequent cathode patterning processing to avoid damage to the third anode 33. The position and shape of the fourth shielding block 514 may be substantially similar to those of the fourth body 34a of the fourth anode 34, and an orthographic projection of the fourth body 34a of the fourth anode 34 on the base substrate may be within a range of an orthographic projection of the fourth shielding block 514 on the base substrate, so that the fourth shielding block 514 may shield the fourth anode 34 during subsequent cathode patterning processing to avoid damage to the fourth anode 34.

In some examples, the anode conductive thin film may be made of a metallic material or a transparent conductive material, and the metallic material may include any one or more of silver (Ag), copper (Cu), aluminum (Al), and molybdenum (Mo), or an alloy material of the above metals. The transparent conductive material may include Indium Tin Oxide (ITO) or Indium Zinc Oxide (IZO). In some examples, the anode conductive thin film may be of a single-layer structure or may be of a multi-layer composite structure, such as ITO/Al/ITO and the like.

(9) Forming a pixel define layer. In some examples, a pixel define thin film is coated on a base substrate 100 where the aforementioned patterns are formed, and the pixel define thin film is patterned by a patterning process to form a pixel define layer (PDL, Pixel Define Layer) 36, as shown in FIG. 4. The pixel define layer 36 is formed with a plurality of pixel openings exposing the anode layer. The pixel define layer 36 within the pixel opening may be removed, exposing the surface of the anode of the sub-pixel where it is located. In some examples, the material of the pixel define layer 36 may include polyimide, or acrylic, or the like.

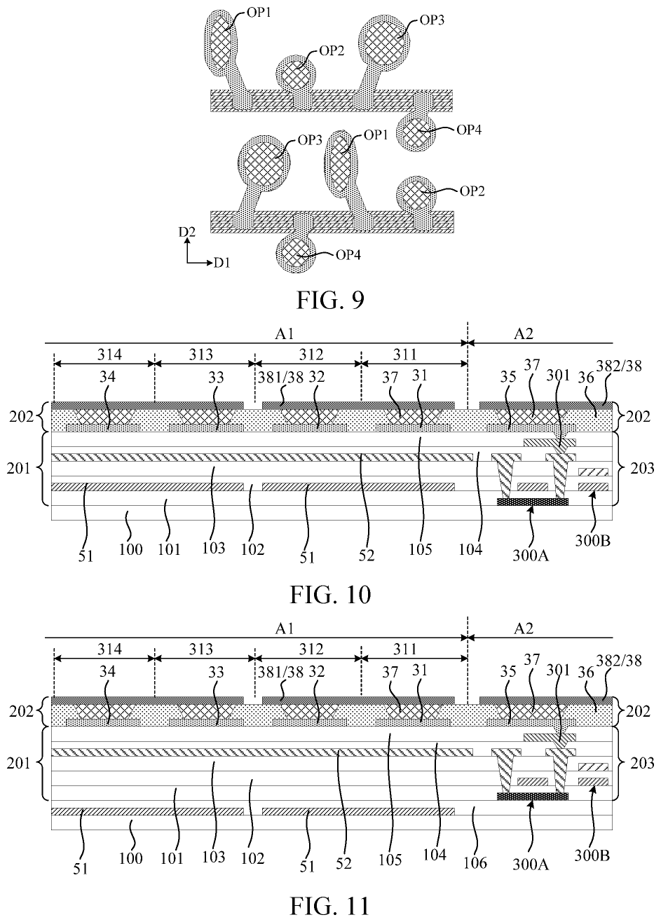

FIG. 9 is a schematic partial plane view of a first display region after forming a pixel define layer according to at least one embodiment of the present disclosure. Pixel openings of two adjacent pixel units (including eight first light emitting elements, the first pixel circuits electrically connected to the eight first light emitting elements being located in the second display region) along the second direction D2 are illustrated in FIG. 9. As shown in FIG. 4 and FIG. 6 to FIG. 9, a first pixel opening OP1 is located at the first light emitting element 311 emitting light of the first color and may expose a part of the surface of the first body 31a of the first anode 31, a second pixel opening OP2 is located in the first light emitting element 312 emitting light of the second color and can expose a part of the surface of the second body 32a of the second anode 32, a third pixel opening OP3 is located in the first light emitting element 313 emitting light of the third color and may expose a part of the surface of the third body 33a of the third anode 33, a fourth pixel opening OP4 is located at the first light emitting element 314 emitting light of the fourth color and may expose a part of the surface of the fourth body 34a of the fourth anode 34.

In some examples, a patterning process of a half tone mask may be employed, and a pattern of a post spacer may be formed when forming the pixel define layer, the post spacer may be disposed outside the pixel opening, and the post spacer may be configured to support the fine metal mask in a subsequent evaporation process. However, the embodiment is not limited thereto.

In some examples, in a direction parallel to the display substrate, the shape of the pixel opening may be a rectangle, square, pentagon, hexagon, circle, or ellipse, or the like. In a direction perpendicular to the display substrate, the cross-sectional shape of the pixel opening may be a rectangle or a trapezoid, etc. The inner side walls of the pixel openings may be planar or cambered. However, the embodiment is not limited thereto.

(10) Forming an organic light emitting layer. In some examples, the organic light emitting layer 37 is formed by evaporation or ink jet printing on the base substrate 100 where the aforementioned structures are formed, as shown in FIG. 4. In some examples, the organic light emitting layer 37 may be located within each sub-pixel of the first display region A1 and the second display region A2 and connected to the anode of this sub-pixel through the pixel opening of this sub-pixel. For example, the organic light emitting layer 37 of the first light emitting element 311 may be configured to emit red light, the organic light emitting layer of the first light emitting element 312 may be configured to emit green light, the organic light emitting layer of the first light emitting element 313 may be configured to emit blue light, and the organic light emitting layer of the first light emitting element 314 may be configured to emit green light. The organic light emitting layer 37 of the second display region A2 may be configured to emit monochromatic light or emit white light. This embodiment is not limited thereto.

In an example, the organic emitting layer may include an Emitting Layer (EML), and any one or more of following: a Hole Injection Layer (HIL), a Hole Transport Layer (HTL), an Electron Block Layer (EBL), a Hole Block Layer (HBL), an Electron Transport Layer (ETL), and an Electron Injection Layer (EIL).

In some examples, the organic light emitting layer may be prepared in the following manner. Firstly, a hole injection layer, a hole transport layer, and an electron block layer are formed sequentially using an evaporation process of an open mask or an ink-jet printing process, and a common layer of the hole injection layer, the hole transport layer, and the electron block layer is formed on a display substrate. Then, a red emitting layer, a green emitting layer, and a blue emitting layer are respectively formed in corresponding sub-pixels using an evaporation process of a fine metal mask or an ink-jet printing process. Emitting layers of adjacent sub-pixels may be overlapped slightly (e.g. an overlapping portion accounts for less than 10% of an area of a pattern of an individual emitting layer) or may be isolated. Subsequently, a hole block layer, an electron transport layer, and an electron injection layer are formed in sequence using an evaporation process of an open mask or an ink-jet printing process. A common layer of the hole blocking layer, the electron transport layer, and the electron injection layer is formed on the display substrate.

In some examples, the organic emitting layer may include a microcavity adjustment layer, so that a thickness of the organic emitting layer between a cathode and an anode satisfies a design of a length of a microcavity. For example, a hole transport layer, an electron blocking layer, a hole blocking layer, or an electron transport layer may be employed as the microcavity adjustment layer. This embodiment is not limited thereto.

In some examples, the light emitting layer may include a host material and a dopant material doped in the host material. The doping ratio of the dopant material of the light emitting layer can be about 1% to 20%. Within a range of the doping ratio, on one hand, the host material of the emitting layer may effectively transfer exciton energy to the dopant material of the emitting layer to excite the dopant material to emit light; on the other hand, the host material “dilutes” the dopant material of the emitting layer, so as to effectively improve fluorescence quenching caused by collisions between molecules of the dopant material of the emitting layer and collisions between energies, and improve a light emitting efficiency and device lifetime. The doping ratio may refer to a ratio of the mass of the dopant material to the mass of the emitting layer, that is, the mass percentage. For example, the thickness of the light emitting layer may be about 10 nm to 50 nm.

(11) Forming a cathode layer. In some examples, a pattern of a cathode layer is formed by evaporation of an open mask on the base substrate where the aforementioned structures are formed. For example, the pattern of the cathode layer located in the first display region and the second display region may be a full-face structure.

In some examples, the cathode layer may be made of any one or more of magnesium (Mg), silver (Ag), aluminum (Al), copper (Cu), and lithium (Li), or an alloy made of any one or more of the above metals. For example, Mg and Ag with good conductivity can be used for the cathode layer.

In some examples, an optical coupling layer may be formed after the pattern of the cathode layer is formed, the optical coupling layer is disposed on the cathode, and a refractive index of the optical coupling layer may be greater than a refractive index of the cathode layer, thus facilitating light extraction and increasing light output efficiency. The material of the optical coupling layer may be an organic material, or an inorganic material, or an organic material and an inorganic material, and the optical coupling layer may be a single layer, a multilayer or a composite layer.

(12) Patterning the cathode. In some examples, on the base substrate where the aforementioned structures are formed, a patterned first cathode layer 381 is formed in the first display region A1 by irradiation from a side of the base substrate away from the light transmitting structure layer using an exposure machine, as shown in FIG. 4. The second cathode layer 382 of the second display region A2 may have a full-face structure. The exposure machine can be an infrared laser device. The patterned first cathode layer 381 is obtained by selectively removing a portion of the cathode and leaving only a pattern of a cathode necessary for light emission. The position and shape of the patterned first cathode layer 381 is substantially the same as those of the shielding layer 51, and an orthographic projection of the patterned first cathode layer 381 on the base substrate may be at least partially overlapped with the orthographic projection of the shielding layer 51 on the base substrate, for example may be completely overlapped.

In this example, since a plurality of anodes and cathodes of the first display region A1 are located at a side of the shielding layer 51 away from the base substrate 100, when the infrared laser device irradiates from the back surface of the display substrate (the side of the base substrate away from the light transmitting structure layer), the shielding layer 51 can be used as a protective layer to protect not only the plurality of anodes from being irradiated by the infrared laser, but also the cathode with an overlapped region with the shielding layer 51, so that the cathode with the overlapped region can be retained since it is not irradiated by the infrared laser, while the cathode without an overlapped region with the shielding layer 51 is removed by being irradiated by the infrared laser, thus forming a patterned cathode.

In the subsequent preparation process, a process such as forming an encapsulation structure layer may be included. For example, a first encapsulation layer, a second encapsulation layer and a third encapsulation layer are formed in sequence. The first encapsulation layer and the third encapsulation layer may be made of an inorganic material, and the second encapsulation layer may be made of an organic material. The encapsulation structure adopts a stacked structure of inorganic, organic and inorganic, which can ensure the integrity of encapsulation and effectively isolate external water and oxygen.

A structure and a manufacturing process of the display substrate of this embodiment are merely illustrative. In some exemplary implementation, a corresponding structure may be changed and a patterning process may be added or removed according to actual needs. The manufacturing process of the exemplary embodiment may be implemented using an existing mature manufacturing device, and may be compatible well with an existing manufacturing process, simple in process implementation, easy to implement, high in a production efficiency, low in a production cost, and high in yield.

The display substrate provided by the embodiment can reduce the number of transparent conductive layers by arranging the shielding layer of the first display region and the second conductive layer of the second display region in the same layer, and the connection layer of the first display region and the third conductive layer of the second display region in the same layer, thereby reducing the preparation steps and reducing the cost. Furthermore, a first connection line electrically connecting the first pixel circuit and the first light emitting element is provided by at least one connection layer, which is beneficial to increase the number of the first connection lines, thereby being beneficial to increase the size of the first display region. For example, if the line width of the first connection line and the spacing between adjacent lines are both designed in the size of 1.5/1.5, the display substrate with three transparent conductive layers can realize the arrangement of connection lines through two transparent conductive layers, which can reduce the preparation process of two transparent conductive layers and greatly reduce the cost. In addition, taking the first display region being a circular region as an example, the radius of the first display region can be approximately increased by 127 microns every time one connection layer is used for arranging connection lines, which is beneficial to the increase of the aperture of the first display region.

FIG. 10 is another partial sectional schematic diagram of a display substrate according to at least one embodiment of the present disclosure. In some examples, as shown in FIG. 10, the shielding layer 51 of the light transmitting structure layer 201 of the first display region A1 may be disposed in the same layer as the second conductive layer of the circuit structure layer 203 of the second display region A2, and the connection layer 52 of the light transmitting structure layer 201 of the first display region A1 may be disposed in the same layer as the fourth conductive layer of the circuit structure layer 203 of the second display region A2. However, the embodiment is not limited thereto. For example, the connection layer 52 of the first display region A1 may be disposed in the same layer as the fifth conductive layer of the second display region A2. Rest of the structure of the display substrate according to this embodiment may refer to descriptions of the aforementioned embodiments, and will not be repeated here.

FIG. 11 is another partial sectional schematic diagram of a display substrate according to at least one embodiment of the present disclosure. In some examples, as shown in FIG. 11, the circuit structure layer 203 of the second display region A2 may include a first conductive layer, a sixth insulation layer 106, a semiconductor layer, a first insulation layer 101, a second conductive layer, a second insulation layer 102, a third conductive layer, a third insulation layer 103, a fourth conductive layer, a fourth insulation layer 104, a fifth conductive layer, and a fifth insulation layer 105 that are sequentially disposed on the base substrate 100. For example, the first conductive layer may include a shielding electrode (not shown) configured to shield a channel region of an active layer of a transistor of a pixel circuit. The first conductive layer may be made of a metallic material, such as any one or more of Argentum (Ag), Copper (Cu), Aluminum (Al), and Molybdenum (Mo), or an alloy material of the abovementioned metals, such as an Aluminum-Neodymium alloy (AlNd) or a Molybdenum-Niobium alloy (MoNb), and may be of a single-layer structure, or a multilayer composite structure such as Mo/Cu/MO, Ti/Al/Ti.

In this example, as shown in FIG. 11, the shielding layer 51 of the light transmitting structure layer 201 of the first display region A1 may be disposed in the same layer as the first conductive layer of the second display region A2. The connection layer 52 of the first display region A1 may be disposed in the same layer as the fourth conductive layer of the second display region A2. However, the embodiment is not limited thereto. For example, the connection layer 52 of the first display region A1 may be disposed in the same layer as the second conductive layer, the third conductive layer, or the fifth conductive layer. Rest of the structure of the display substrate according to this embodiment may refer to descriptions of the aforementioned embodiments, and will not be repeated here.

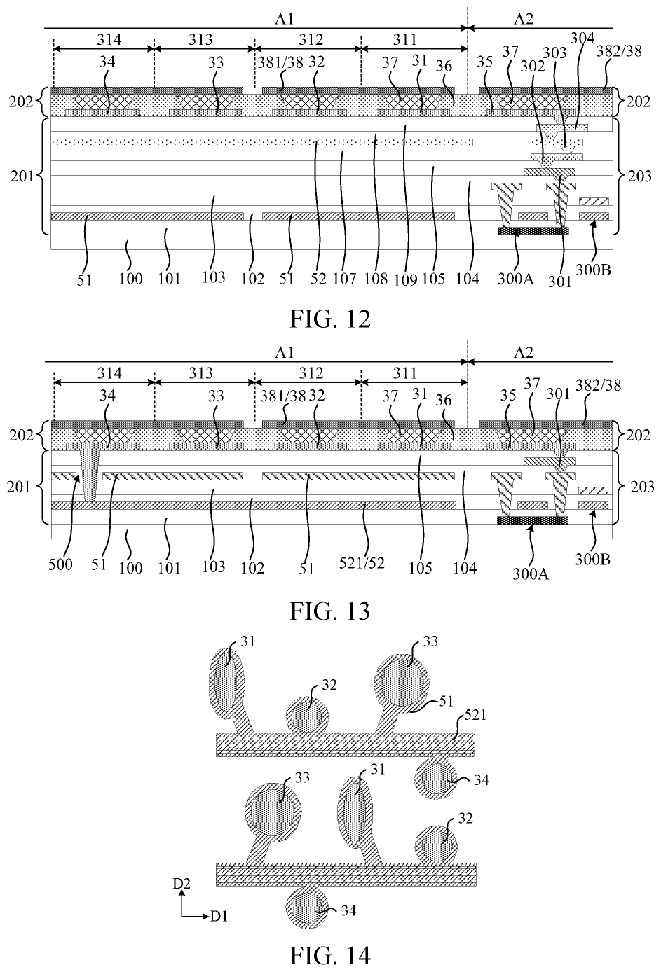

FIG. 12 is another partial sectional schematic diagram of a display substrate according to at least one embodiment of the present disclosure. In some examples, as shown in FIG. 12, the circuit structure layer 203 of the second display region A2 may include a semiconductor layer, a first insulation layer 101, a second conductive layer, a second insulation layer 102, a third conductive layer, a third insulation layer 103, a fourth conductive layer, a fourth insulation layer 104, a fifth conductive layer, a fifth insulation layer 105, a first transparent conductive layer, a seventh insulation layer 107, a second transparent conductive layer, an eighth insulation layer 108, a third transparent conductive layer, and a ninth insulation layer 109 that are sequentially disposed on the base substrate 100. The first transparent conductive layer may include a third anode connection electrode 302, the second transparent conductive layer may include a fourth anode connection electrode 303, and the third transparent conductive layer may include a fifth anode connection electrode 304. The anode of the second light emitting element (e.g. the fifth anode 35) may be electrically connected to the second pixel circuit through the fifth anode connection electrode 304, the fourth anode connection electrode 303, the third anode connection electrode 302 and the first anode connection electrode 301 in sequence. The first transparent conductive layer, the second transparent conductive layer and the third transparent conductive layer may be made of a transparent conductive material such as ITO. The shielding layer 51 of the first display region A1 may be disposed in the same layer as the second conductive layer of the second display region A2, and the connection layer 52 of the first display region A1 may be disposed in the same layer as the second transparent conductive layer of the second display region A2. However, the embodiment is not limited thereto. For example, the display substrate may include three connection layers disposed in the same layer as the first transparent conductive layer, the second transparent conductive layer and the third transparent conductive layer, respectively, and a first connection line of the three connection layers may extend from the first display region A1 to the second display region A2 to realize an electrical connection between the first light emitting element and the first pixel circuit. Rest of the structure of the display substrate according to this embodiment may refer to descriptions of the aforementioned embodiments, and will not be repeated here.

In other examples, taking the shielding layer and the first conductive layer being disposed in the same layer as an example, the display substrate includes a plurality of connection layers, wherein one connection layer may be disposed in the same layer as one of the second conductive layer to the fifth conductive layer, and the rest connection layers may be disposed in the same layer as at least one of the first transparent conductive layer and the third transparent conductive layer.

FIG. 13 is another partial sectional schematic diagram of a display substrate according to at least one embodiment of the present disclosure. In some examples, as shown in FIG. 13, the circuit structure layer 203 of the second display region A2 may include a semiconductor layer, a first insulation layer 101, a second conductive layer, a second insulation layer 102, a third conductive layer, a third insulation layer 103, a fourth conductive layer, a fourth insulation layer 104, a fifth conductive layer, and a fifth insulation layer 105 that are sequentially disposed on the base substrate 100. The shielding layer 51 of the first display region A1 may be located at a side of the connection layer 52 away from the base substrate 100. For example, the shielding layer 51 may be disposed in the same layer as the fourth conductive layer of the second display region A2, and the connection layer 52 may be disposed in the same layer as the second conductive layer of the second display region A2. The shielding layer 51 may include a hollow part 500. Taking the connection of the fourth anode 34 of the first light emitting element 314 to the first connection line 521 as an example, the fourth anode 34 may be electrically connected to the first connection line 521 through an anode connection via, and the fifth insulation layer 105, the fourth insulation layer 104, the third insulation layer 103 and the second insulation layer 102 in the anode connection via may be removed to expose the surface of the first connection line 521. An orthographic projection of the anode connection via on the base substrate may be within a range of an orthographic projection of the hollow part 500 of the shielding layer 51 on the base substrate. For example, the hollow part 500 corresponding to the anode connection via by which the fourth Anode 34 is connected to the first connection line 521 may be located in the fourth shielding block or the region of the shielding strip adjacent to the fourth shielding block. In some examples, the orthographic projection of the hollow part 500 on the base substrate may be rectangular, circular, pentagonal, or hexagonal. However, the embodiment is not limited thereto. In this example, when the shielding layer is located at a side of the connection layer away from the base substrate and close to the light emitting structure layer, the hollow part is provided by the shielding layer to realize the electrical connection between the first light emitting element and the first connection line of the connection layer. In some examples, the orthographic projection of the hollowed part of the shielding layer on the base substrate may be within a range of the orthographic projection of the connection layer on the base substrate, thereby ensuring the effect of cathode patterning. Rest of the structure of the display substrate according to this embodiment may refer to descriptions of the aforementioned embodiments, and will not be repeated here.

FIG. 14 is another schematic partial plane view of a first display region after forming an anode layer according to at least one embodiment of the present disclosure. An anode structure of two pixel units (including eight first light emitting elements, and the first pixel circuits corresponding to the eight first light emitting elements being located in the second display region) adjacent along the second direction D2 is illustrated in FIG. 14. In some examples, as shown in FIG. 14, the first anode 31 of the first light emitting element emitting light of the first color may be generally elliptical, the second anode 32 of the first light emitting element emitting light of the second color may be generally circular, the third anode 33 of the first light emitting element emitting light of the third color may be generally circular, and the fourth anode 34 of the first light emitting element emitting the fourth color light may be generally circular. An orthographic projection of the first anode 31 on the base substrate may be within a range of an orthographic projection of the first shielding block of the shielding layer 51 on the base substrate. An orthographic projection of the second anode 32 on the base substrate may be within a range of an orthographic projection of the second shielding block of the shielding layer 51 on the base substrate. An orthographic projection of the third anode 33 on the base substrate may be within a range of an orthographic projection of the third shielding block of the shielding layer 51 on the base substrate. An orthographic projection of the fourth anode 34 on the base substrate may be within a range of an orthographic projection of the fourth shielding block of the shielding layer 51 on the base substrate. Rest of the structure of the display substrate according to this embodiment may refer to descriptions of the aforementioned embodiments, and will not be repeated here.

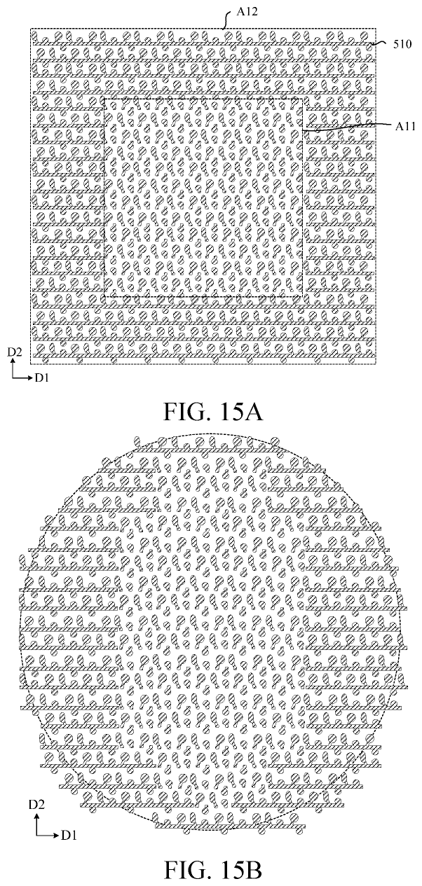

FIG. 15A and FIG. 15B are other schematic plane views of a shielding layer of a first display region of a display substrate according to at least one embodiment of the present disclosure. In some examples, as shown in FIG. 15A, the aforementioned first region may be a rectangular first display region. The first region may include a first sub-region A11 and a second sub-region A12 surrounding the first sub-region A11. The shielding layer within the second sub-region A12 may include a shielding strip 510 and a plurality of shielding blocks connected to the shielding strip 510 (e.g. the aforementioned first to fourth shielding blocks). The shielding layer within the first sub-region A11 may include a plurality of shielding blocks disposed independently.

In some examples, as shown in FIG. 15B, the aforementioned first region may be a circular first display region. A first sub-region of the first region may be a middle region, and the shielding layer of the first sub-region may include a shielding strip and a plurality of shielding blocks connected with the shielding strip; a second sub-region of the first region may be a peripheral region surrounding the middle region, and the shielding layer within the second sub-region may include a plurality of shielding blocks disposed independently.

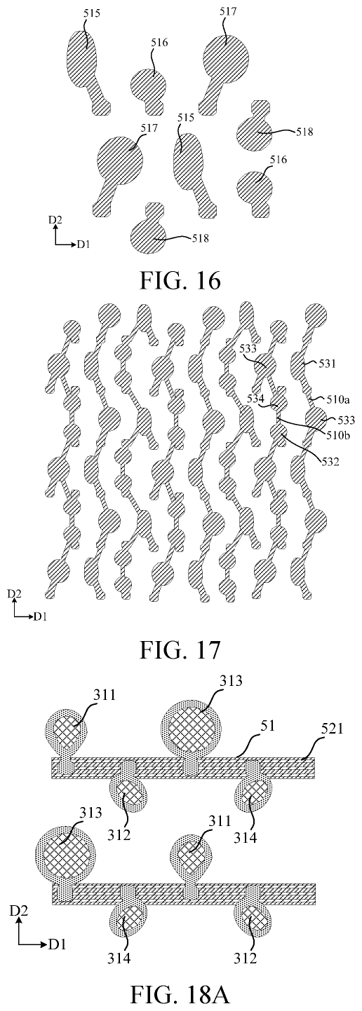

FIG. 16 is another schematic partial plane view of a shielding layer according to at least one embodiment of the present disclosure. FIG. 16 is a partial schematic view of the shielding layer within the first sub-region in FIG. 15A and FIG. 15B. FIG. 16 illustrates a structure of the shielding layer corresponding to two pixel units (including eight first light emitting elements, the first pixel circuits corresponding to the eight first light emitting elements being located in the second display region) adjacent along the second direction D2.

In some examples, as shown in FIG. 16, the shielding layer of the first sub-region may include a fifth shielding block 515, a sixth shielding block 516, a seventh shielding block 517 and an eighth shielding block 518 which are independently disposed. The fifth shielding block 515 to the eighth shielding block 518 may be disposed along the first direction D1. The position and shape of the fifth shielding block 515 may be similar to the position and shape of the first anode of the first light emitting element emitting light of the first color, the position and shape of the sixth shielding block 516 may be similar to the position and shape of the second anode of the first light emitting element emitting light of the second color, the position and shape of the seventh shielding block 517 may be similar to the position and shape of the third anode of the first light emitting element emitting light of the third color, and the position and shape of the eighth shielding block 518 may be similar to the position and shape of the fourth anode of the first light emitting element emitting light of the fourth color.

In some examples, as shown in FIG. 15A to FIG. 16, the first light emitting element in the first sub-region A11 may be electrically connected with the first pixel circuit of the second display region through a first connection line made of a transparent conductive material, and the first light emitting element in the second sub-region A12 may be electrically connected with the first pixel circuit of the second display region through a first connection line made of a metallic material. For example, the connection layer where the first connection line electrically connected with the first light emitting element in the first sub-region A11 is located may be disposed in the same layer as the first transparent conductive layer, the second transparent conductive layer or the third transparent conductive layer in the second display region. The connection layer where the first connection line electrically connected to the first light emitting element in the second sub-region A12 is located may be disposed in the same layer as one of the first conductive layer to the fifth conductive layer in the second display region. However, the embodiment is not limited thereto. In other examples, all of the first light emitting elements within the first region may be electrically connected to the first pixel circuit of the second display region through the first connection line made of the metallic material. The present example can improve diffraction problems caused by the shielding strips by providing a shielding layer in a partial region of the first region with removing the shielding strips extending along the first direction.

Rest of the structure of the display substrate according to this embodiment may refer to descriptions of the aforementioned embodiments, and will not be repeated here.

FIG. 17 is another schematic partial plane view of a shielding layer according to at least one embodiment of the present disclosure. In some examples, as shown in FIG. 17, the shielding layer of the first display region may include a first shielding strip 510a, a second shielding strip 510b, a plurality of shielding blocks connected to the first shielding strip 510a (e.g. including an eleventh shielding block 531, a thirteenth shielding block 533), and a plurality of shielding blocks connected to the second shielding strip 510b (e.g. including a twelfth shielding block 532, a thirteenth shielding block 533, and a fourteenth shielding block 534). The first shielding strip 510a and the second shielding strip 510b may respectively extend substantially along the second direction D2, and the first shielding strip 510a and the second shielding strip 510b may be arranged at intervals along the first direction D1.

In some examples, as shown in FIG. 17, the position and shape of the eleventh shielding block 531 may be similar to the position and shape of the first anode of the first light emitting element emitting light of the first color. The position and shape of the twelfth blocking block 532 may be similar to the position and shape of the second anode of the first light emitting element emitting light of the second color. The position and shape of the thirteenth shielding block 533 may be similar to the position and shape of the third anode of the first light emitting element emitting light of the third color. The position and shape of the fourteenth blocking block 534 are similar to the position and shape of the fourth anode of the first light emitting element emitting the fourth color light.

In some examples, an orthographic projection of an extended part of at least one first connection line of the connection layer along the second direction D2 on the base substrate may be within a range of an orthographic projection of the first shielding strip or the second shielding strip of the shielding layer on the base substrate. The pattern of the shielding layer can be matched with the direction of the first connection line. The extending direction of the shielding strip of the shielding layer is parallel to the first direction D1, or the second direction D2, or may intersect with both the first direction D1 and the second direction D2. The shielding strip can be linear or curved arc. However, the embodiment is not limited thereto. Rest of the structure of the display substrate according to this embodiment may refer to descriptions of the aforementioned embodiments, and will not be repeated here.

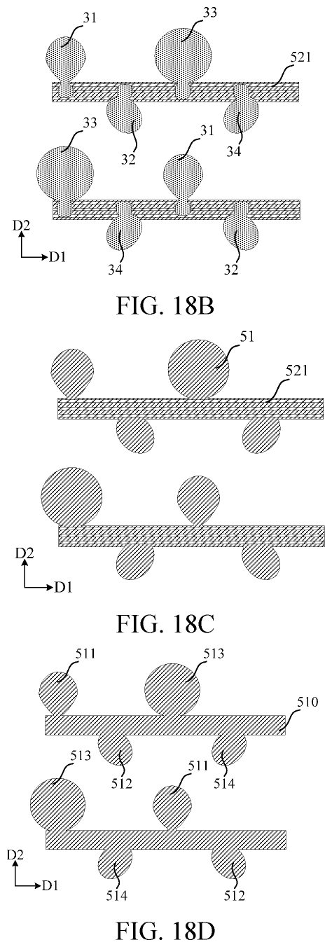

FIG. 18A to FIG. 18D are schematic partial diagrams of a first display region according to at least one embodiment of the present disclosure. FIG. 18A illustrates a structure of two pixel units (including eight first light emitting elements, and the first pixel circuits electrically connected with the eight first light emitting elements being located in the second display region) disposed in the first display region along the second direction D2. Each pixel unit may include four first light emitting elements, the four first light emitting elements may be disposed along the first direction D1. FIG. 18A illustrates a partial structure of the first display region after the pixel define layer is formed. FIG. 18B illustrates a partial structure of the first display region after the anode layer is formed. FIG. 18C illustrates a partial structure of the first display region after the connection layer is formed. FIG. 18D illustrates a partial structure of the first display region after the shielding layer is formed.

In some examples, as shown in FIG. 18A to FIG. 18D, the shielding layer may include a shielding strip 510 extending along the first direction D1 and a first shielding block 511, a second shielding block 512, a third shielding block 513, and a fourth shielding block 514 connected to the shielding strip 510. For example, the first shielding block 511 may be substantially in a shape of water droplet, the third shielding block 513 may be substantially circular, and the second shielding block 512 and the fourth shielding block 514 may be substantially elliptical. The first shielding block 511 and the third shielding block 513 may be located at one side of the shielding strip 510 along the second direction D2, and the second shielding block and the fourth shielding block 514 may be located at the other side of the shielding strip 510 along the second direction D2.

In some examples, as shown in FIG. 18A-FIG. 18D, the shielding layer may be located at a side of the connection layer close to the base substrate. The connection layer includes a plurality of first connection lines 521. An orthographic projection of an extended part of the first connection line 521 along the first direction DI on the base substrate is located within a range of an orthographic projection of the shielding strip 510 on the base substrate. The position and shape of the first anode 31 of the first light emitting element 311 emitting light of the first color may correspond to the first shielding block 511, the position and shape of the second anode 32 of the first light emitting element 312 emitting light of the second color may correspond to the second shielding block 512, the position and shape of the third anode 33 of the first light emitting element 313 emitting light of the third color may correspond to the third shielding block 513, and the position and shape of the fourth anode 34 of the first light emitting element 314 emitting the fourth color light may correspond to the fourth shielding block 514.

In this example, the arrangement of the first light emitting elements to the fourth light emitting elements is different from that of the foregoing embodiments. Rest of the structure of the display substrate according to this embodiment may refer to descriptions of the aforementioned embodiments, and will not be repeated here.

The embodiment also provides a preparation method for a display substrate, wherein the display substrate includes a first region and a second region located on at least one side of the first region. The preparation method includes: forming a light transmitting structure layer on the base substrate of the first region and forming a circuit structure layer on the base substrate of the second region; forming a light emitting structure layer on a side of the circuit structure layer and the light transmitting structure layer away from the base substrate, wherein the light emitting structure layer at least includes a plurality of first light emitting elements located in the first region; forming a patterned cathode of the light emitting structure layer in the first region. The circuit structure layer at least includes a plurality of first pixel circuits. The light transmitting structure layer includes a shielding layer and at least one connection layer, wherein at least one connection layer includes a plurality of first connection lines, and at least one first connection line of the plurality of first connection lines extends from the first region to the second region. An orthographic projection of the shielding layer on the base substrate is at least partially overlapped with an orthographic projection of at least one connection layer on the base substrate. At least one of the plurality of first light emitting elements in the first region is electrically connected to at least one of the plurality of first pixel circuits in the second region through at least one first connection line. The shielding layer is configured as a shielding structure in a cathode patterning process such that an orthographic projection of the patterned cathode on the base substrate is at least partially overlapped with an orthographic projection of the shielding layer on the base substrate.

In some exemplary embodiments, forming the light transmitting structure layer on the base substrate of the first region and forming the circuit structure layer on the base substrate of the second region includes: forming a semiconductor layer on the base substrate of the second region, wherein the semiconductor layer at least includes an active layer of a transistor of a first pixel circuit; forming a shielding layer in the first region and forming a second conductive layer in the second region synchronously, wherein the second conductive layer includes a gate electrode of a transistor and a first plate of a storage capacitor of the first pixel circuit; forming a connection layer in the first region and forming a third conductive layer in the second region synchronously, wherein the third conductive layer includes a second plate of the storage capacitor of the first pixel circuit; and forming a fourth conductive layer in the second region, wherein the fourth conductive layer includes a first electrode and a second electrode of the transistor of the first pixel circuit.

The preparation process of the display substrate according to the embodiment may refer to descriptions of the aforementioned embodiments, and thus will not be repeated here.

An embodiment of the present disclosure also provides a display apparatus, which includes the aforementioned display substrate.

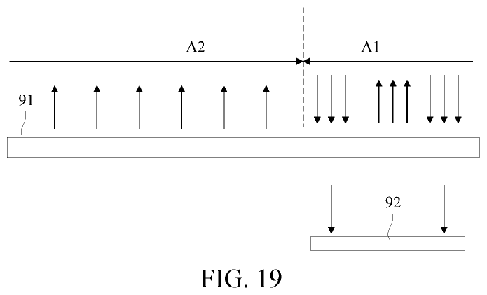

FIG. 19 is a schematic diagram of a display apparatus according to at least one embodiment of the present disclosure. As shown in FIG. 19, an embodiment provides a display apparatus, which includes a display substrate 91 and a sensor 92 located at a non-display side away from the display substrate 91. An orthographic projection of the sensor 92 on the display substrate 91 is overlapped with the first display region A1.

In some examples, the display substrate 91 may be a flexible OLED display substrate, a QLED display substrate, a Micro-LED display substrate, or a Mini-LED display substrate. The display apparatus may be any product or component with a display function such as an OLED display, a cell phone, a tablet, a television, a display, a laptop, a digital photo frame, and a navigator, which is not limited in the embodiments of the present disclosure.

The drawings of the present disclosure only involve structures involved in the present disclosure, and other structures may refer to conventional designs. The embodiments of the present disclosure and features in the embodiments may be combined to each other to obtain new embodiments if there is no conflict. Those of ordinary skills in the art should understand that modifications or equivalent replacements may be made to the technical solutions of the present disclosure without departing from the essence and scope of the technical solutions of the present disclosure, and shall all fall within the scope of the claims of the present disclosure.

1. A display substrate, comprising:
a base substrate, comprising a first region and a second region located on at least one side of the first region;
a circuit structure layer, located in the second region and at least comprising a plurality of first pixel circuits,
a light transmitting structure layer, located in the first region, comprising a shielding layer and at least one connection layer, wherein the at least one connection layer comprises a plurality of first connection lines, and at least one first connection line of the plurality of first connection lines extends from the first region to the second region; an orthographic projection of the shielding layer on the base substrate is at least partially overlapped with an orthographic projection of the at least one connection layer on the base substrate; and
a light emitting structure layer, located at a side of the circuit structure layer and the light transmitting structure layer away from the base substrate, at least comprising a plurality of first light emitting elements located in the first region, wherein at least one of the plurality of first light emitting elements of the first region is electrically connected with at least one of the plurality of first pixel circuits of the second region through the at least one first connection line;
wherein the light emitting structure layer comprises a patterned cathode located in the first region; the shielding layer is configured as a shielding structure in a cathode patterning process to cause an orthographic projection of the patterned cathode on the base substrate to be at least partially overlapped with an orthographic projection of the shielding layer on the base substrate.

2. The display substrate according to claim 1, wherein the shielding layer is located at a side of the at least one connection layer close to the base substrate.

3. The display substrate according to claim 1, wherein a material of the at least one connection layer is a metallic material or an oxide material.

4. The display substrate according to claim 1, wherein the shielding layer comprises: a shielding strip extending along a first direction, and a plurality of shielding blocks connected to the shielding strip;
in the first region, an orthographic projection of an extended part of at least one first connection line of the at least one connection layer along the first direction on the base substrate is within a range of an orthographic projection of the shielding strip on the base substrate.

5. The display substrate according to claim 1, wherein the first region comprises: a first sub-region and a second sub-region, the second sub-region is located on at least one side of the first sub-region;
the shielding layer of the second sub-region comprises a shielding strip extending along the first direction and a plurality of shielding blocks connected with the shielding strip, the shielding layer of the first sub-region comprises a plurality of shielding blocks independently arranged.

6. The display substrate according to claim 5, wherein a material of a first connection line electrically connected to at least one first light emitting element in the second sub-region is different from a material of a first connection line electrically connected to at least one first light emitting element in the first sub-region.

7. The display substrate according to claim 4, wherein the shielding strip and the plurality of shielding blocks connected to the shielding strip are of an integral structure.

8. The display substrate according to claim 1, wherein the light emitting structure layer further comprises: a patterned anode located in the first region, an orthographic projection of the anode in the first region on the base substrate is within a range of an orthographic projection of the shielding layer on the base substrate.

9. The display substrate according to claim 1, wherein the circuit structure layer comprises: a first conductive layer, a semiconductor layer, a second conductive layer, a third conductive layer, a fourth conductive layer, and a fifth conductive layer disposed on the base substrate;
the shielding layer and one of the first conductive layer, the second conductive layer, the third conductive layer, the fourth conductive layer and the fifth conductive layer are disposed in a same layer, and the at least one connection layer and the shielding layer are located in different film layers.

10. The display substrate according to claim 9, wherein the circuit structure layer further comprises: a first transparent conductive layer, a second transparent conductive layer, and a third transparent conductive layer located at a side of the fourth conductive layer away from the base substrate;
the at least one connection layer and at least one of the first transparent conductive layer, the second transparent conductive layer and the third transparent conductive layer are disposed in a same layer.

11. The display substrate according to claim 1, wherein the plurality of first light emitting elements in the first region comprise a first light emitting element emitting light of a first color, a first light emitting element emitting light of a second color, a first light emitting element emitting light of a third color, and a first light emitting element emitting light of a fourth color;
the shielding layer at least comprises a first shielding block, a second shielding block, a third shielding block and a fourth shielding block; the first shielding block, the second shielding block, the third shielding block and the fourth shielding block are disposed along the first direction;
an orthographic projection of an anode of the first light emitting element emitting light of the first color on the base substrate is within a range of an orthographic projection of the first shielding block on the base substrate, an orthographic projection of an anode of the first light emitting element emitting light of the second color on the base substrate is within a range of an orthographic projection of the second shielding block on the base substrate, an orthographic projection of an anode of the first light emitting element emitting light of the third color on the base substrate is within a range of an orthographic projection of the third shielding block on the base substrate, an orthographic projection of an anode of the first light emitting element emitting the fourth color light on the base substrate is within a range of an orthographic projection of the fourth shielding block on the base substrate.

12. The display substrate according to claim 11, wherein the shielding layer further comprises: a shielding strip connecting the first shielding block, the second shielding block, the third shielding block, and the fourth shielding block;
the first shielding block, the second shielding block and the third shielding block are located at a side of the shielding strip in a second direction, and the fourth shielding block is located at another side of the shielding strip in the second direction; the second direction intersects with the first direction.

13. The display substrate according to claim 11, wherein the shielding layer further comprises: a shielding strip connecting the first shielding block, the second shielding block, the third shielding block, and the fourth shielding block;
the first shielding block and the third shielding block are located at a side of the shielding strip in a second direction, and the second shielding block and the fourth shielding block are located at another side of the shielding strip in the second direction; the second direction intersects with the first direction.

14. The display substrate according to claim 1, wherein the shielding layer is located at a side of the at least one connection layer away from the base substrate; the shielding layer comprises a hollow part, the at least one first connection line is electrically connected with an anode of the first light emitting element through an anode connection via, and an orthographic projection of the anode connection via on the base substrate is within a range of an orthographic projection of the hollow part on the base substrate.

15. A display apparatus, comprising: the display substrate according to claim 1, and a sensor located at a non-display side of the display substrate, wherein an orthographic projection of the sensor on the display substrate is overlapped with the first region of the display substrate.

16. A preparation method for a display substrate, wherein the display substrate comprises a first region and a second region located on at least one side of the first region, the method comprises:
forming a light transmitting structure layer on the base substrate of the first region and forming a circuit structure layer on the base substrate of the second region; wherein the circuit structure layer at least comprises a plurality of first pixel circuits, the light transmitting structure layer comprises a shielding layer and at least one connection layer, the at least one connection layer comprises a plurality of first connection lines, and at least one first connection line of the plurality of first connection lines extends from the first region to the second region, an orthographic projection of the shielding layer on the base substrate is at least partially overlapped with an orthographic projection of the at least one connection layer on the base substrate;
forming a light emitting structure layer at a side of the circuit structure layer and the light transmitting structure layer away from the base substrate, wherein the light emitting structure layer at least comprises a plurality of first light emitting elements located in the first region, at least one of the plurality of first light emitting elements of the first region is electrically connected with at least one of the plurality of first pixel circuits of the second region through the at least one first connection line; and
forming a patterned cathode of the light emitting structure layer in the first region, wherein the shielding layer is configured as a shielding structure in a cathode patterning process to cause an orthographic projection of the patterned cathode on the base substrate is at least partially overlapped with an orthographic projection of the shielding layer on the base substrate.

17. The preparation method according to claim 16, wherein, forming the light transmitting structure layer on the base substrate of the first region and forming the circuit structure layer on the base substrate of the second region comprises:
forming a semiconductor layer on the base substrate of the second region, wherein the semiconductor layer at least comprises an active layer of a transistor of a first pixel circuit;
forming a shielding layer in the first region and forming a second conductive layer in the second region synchronously, wherein the second conductive layer comprises a gate electrode of the transistor and a first plate of a storage capacitor of the first pixel circuit;
forming a connection layer in the first region and forming a third conductive layer in the second region synchronously, wherein the third conductive layer comprises a second plate of the storage capacitor of the first pixel circuit; and
forming a fourth conductive layer in the second region, wherein the fourth conductive layer comprises a first electrode and a second electrode of the transistor of the first pixel circuit.

18. The display substrate according to claim 2, wherein a material of the at least one connection layer is a metallic material or an oxide material.

19. The display substrate according to claim 2, wherein the shielding layer comprises: a shielding strip extending along a first direction, and a plurality of shielding blocks connected to the shielding strip;
in the first region, an orthographic projection of an extended part of at least one first connection line of the at least one connection layer along the first direction on the base substrate is within a range of an orthographic projection of the shielding strip on the base substrate.

20. The display substrate according to claim 3, wherein the shielding layer comprises: a shielding strip extending along a first direction, and a plurality of shielding blocks connected to the shielding strip;
in the first region, an orthographic projection of an extended part of at least one first connection line of the at least one connection layer along the first direction on the base substrate is within a range of an orthographic projection of the shielding strip on the base substrate.
